(19) United States
(12) Patent Application Publication
(10) Pub. No.: US 2026/0012289 A1
(43) Pub. Date: Jan. 8, 2026

(54) Data Transmission Method, Apparatus, and System

(71) Applicant: Huawei Technologies Co., Ltd., Shenzhen (CN)

(72) Inventors: Xiang He, Beijing (CN); Hao Ren, Beijing (CN)

(21) Appl. No.: 19/267,023

(22) Filed: Jul. 11, 2025

Related U.S. Application Data
(63) Continuation of application No. PCT/CN2024/076188, filed on Feb. 5, 2024.

(51) Int. Cl. H04L 1/00; H03M 13/15

(52) U.S. Cl. CPC H04L 1/0057; H03M 13/1515; H04L 1/0071

(57) ABSTRACT

In a data transmission method, a transmitting end multiplexes a data streams based on a symbol group to obtain b data streams, where a is an integer greater than or equal to 2, b is an integer greater than or equal to 1 and b<a, any one of the b data streams includes a plurality of symbol groups, any symbol group includes a plurality of symbols from different codewords, and any symbol includes a plurality of bits; and the transmitting end transmits the b data streams. The transmitting end performs the multiplexing based on the symbol group including the symbols.

### CROSS-REFERENCE TO RELATED APPLICATIONS

This is a continuation of Int'l Patent App. No. PCT/CN2024/076188, filed on Feb. 5, 2024, which is incorporated by reference.

### FIELD

This disclosure pertains to the field of communication technologies, and in particular, to a data transmission method and apparatus, and a system.

### BACKGROUND

An architecture of a high-speed Ethernet interface includes a physical medium attachment (PMA) layer. The PMA layer is configured to perform transmission rate conversion on data. The PMA layer performs data processing in a bit multiplexing (Bit Mux) manner. In an example of a transmitting end, the PMA layer multiplexes, in a unit of a bit, m received data streams obtained based on symbol interleaving, to obtain n data streams, where the n data streams are output through a PMA lane. In a process in which the transmitting end transmits data to a receiving end, if a burst error exists in the transmitted data, for example, burst error data of a plurality of consecutive bits exists in a data stream in the n data streams, when the receiving end demultiplexes the n data streams, the burst error data of the plurality of consecutive bits is demultiplexed into a plurality of symbols of a plurality of streams, and the burst error is greatly spread. Consequently, difficulty of error correction at the receiving end is increased, and system reliability is reduced.

### SUMMARY

Embodiments provide a data transmission method and apparatus, and a system, to reduce error correction difficulty and improve system reliability.

According to a first aspect, a data transmission method is provided. The method includes: multiplexing a data streams based on a symbol group to obtain b data streams, where a is an integer greater than or equal to 2, b is an integer greater than or equal to 1 and b<a, any one of the b data streams includes a plurality of symbol groups, any symbol group includes a plurality of symbols from different codewords, and any symbol includes a plurality of bits; and transmitting the b data streams. In the foregoing method, a transmitting end performs the multiplexing based on the symbol group, so that burst error data of a plurality of consecutive bits generated in a transmission process can be prevented from being demultiplexed into a plurality of symbols of a plurality of streams. This helps reduce spreading of a burst error, reduce error correction difficulty, and improve system reliability.

In a possible implementation, the a data streams include a first data stream and a second data stream, the b data streams include a third data stream, the plurality of symbol groups include a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

In a possible implementation, the a data streams are based on Reed-Solomon (RS) encoding, and the symbol is an RS symbol. A length of the RS symbol is 10 bits.

In a possible implementation, a is equal to 8, b is equal to 1, a quantity of symbols included in the symbol group is 2, and any eight consecutive symbol groups included in the b data streams respectively come from the eight data streams. This implementation belongs to a 200GBASE-R technology, and two symbols included in a symbol group come from different codewords in a same codeword group.

In a possible implementation, before the multiplexing a data streams based on a symbol group to obtain b data streams, the method further includes: delaying, by L symbols, sending of a data stream output through each lane with an odd sequence number in the a data streams, where L is equal to 136*N+1, and N is an integer greater than or equal to 1. In this implementation, an order of codewords to which consecutive symbols output through a lane with any even sequence number in the a data streams before the delayed sending belong is different from an order of codewords to which consecutive symbols output through a lane with any odd sequence number in the a data streams before the delayed sending belong. After the delayed sending, codewords to which consecutive symbols output through any two lanes in the a data streams belong are sorted in a same order.

In a possible implementation, a is equal to 16, b is equal to 2, a quantity of symbols included in the symbol group is 2, and any eight consecutive symbol groups included in any one of the b data streams respectively come from eight data streams in the a data streams. This implementation belongs to a 400GBASE-R technology, and two symbols included in a symbol group come from different codewords in a same codeword group.

In a possible implementation, before the multiplexing a data streams based on a symbol group to obtain b data streams, the method further includes: delaying, by L symbols, sending of a data stream output through each lane with an odd sequence number in the a data streams, where L is equal to 68*N+1, and N is an integer greater than or equal to 1. In this implementation, an order of codewords to which consecutive symbols output through a lane with any even sequence number in the a data streams before the delayed sending belong is different from an order of codewords to which consecutive symbols output through a lane with any odd sequence number in the a data streams before the delayed sending belong. After the delayed sending, codewords to which consecutive symbols output through any two lanes in the a data streams belong are sorted in a same order.

In a possible implementation, a is equal to 16, b is equal to 8, a quantity of symbols included in the symbol group is 4, and any two consecutive symbol groups included in any one of the b data streams respectively come from two data streams in the a data streams. This implementation belongs to a 1.6TBASE-R technology, and two symbols included in a symbol group come from different codewords in a same codeword group. An order of codewords to which consecutive symbols output through any lane with an even sequence number in the a data streams belong is the same as an order of codewords to which consecutive symbols output through any lane with an odd sequence number in the a data streams belong.

In a possible implementation, a is equal to 32, b is equal to 4, a quantity of symbols included in the symbol group is 2, and any eight consecutive symbol groups included in any one of the b data streams respectively come from eight data streams in the a data streams, where the eight data streams in the a data streams include four data streams from a first codeword group and four data streams from a second codeword group, the first codeword group includes two codewords, the second codeword group includes two codewords, and the two codewords included in the first codeword group are different from the two codewords included in the second codeword group. This implementation belongs to an 800GBASE-R technology.

In a possible implementation, before the multiplexing a data streams based on a symbol group to obtain b data streams, the method further includes: delaying, by L symbols, sending of a data stream output through each lane with an odd sequence number in the a data streams, where L is equal to 2*N+1, and N is an integer greater than or equal to 0. In this implementation, an order of codewords to which consecutive symbols that come from a same codeword group and that are output through a lane with any even sequence number in the a data streams before the delayed sending belong is different from an order of codewords to which consecutive symbols that come from a same codeword group and that are output through a lane with any odd sequence number in the a data streams before the delayed sending belong. An order of codewords to which consecutive symbols that come from a same codeword group and that are output through a lane with any even sequence number in the a data streams after the delayed sending belong is the same as an order of codewords to which consecutive symbols that come from a same codeword group and that are output through a lane with any odd sequence number in the a data streams after the delayed sending belong.

In a possible implementation, the method further includes: encoding received data to obtain K codeword groups, where K is an integer greater than or equal to 1, and a quantity of symbols included in any codeword in the K codeword groups is a positive integer multiple of 544; and interleaving, based on the symbol, codewords included in the K codeword groups, to obtain the a data streams.

In a possible implementation, the encoding includes forward error correction (FEC) encoding.

In a possible implementation, a sum of rates of the a data streams is the same as a sum of rates of the b data streams.

In a possible implementation, a rate of any one of the b data streams is 200 gigabits per second (Gbps).

According to a second aspect, a data transmission method is provided. The method includes: receiving b data streams, where b is an integer greater than or equal to 1, any one of the b data streams includes a plurality of symbol groups, any symbol group includes a plurality of symbols from different codewords, and any symbol includes a plurality of bits; and demultiplexing the b data streams based on the symbol group to obtain a data streams, where a is an integer greater than or equal to 2, and a>b.

In a possible implementation, the a data streams include a first data stream and a second data stream, the b data streams include a third data stream, the plurality of symbol groups include a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

In a possible implementation, the a data streams are based on RS encoding, and the symbol is an RS symbol.

In a possible implementation, a length of the RS symbol is 10 bits.

According to a third aspect, a data transmission apparatus is provided. The apparatus includes a processor and a transmitter coupled to the processor. The processor is configured to multiplex a data streams based on a symbol group to obtain b data streams, where a is an integer greater than or equal to 2, b is an integer greater than or equal to 1 and b<a, any one of the b data streams includes a plurality of symbol groups, any symbol group includes a plurality of symbols from different codewords, and any symbol includes a plurality of bits. The transmitter is configured to transmit the b data streams.

In a possible implementation, the a data streams include a first data stream and a second data stream, the b data streams include a third data stream, the plurality of symbol groups include a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

In a possible implementation, the a data streams are based on RS encoding, and the symbol is an RS symbol.

In a possible implementation, a length of the RS symbol is 10 bits.

In a possible implementation, a is equal to 8, b is equal to 1, a quantity of symbols included in the symbol group is 2, and any eight consecutive symbol groups included in the b data streams respectively come from the eight data streams.

In a possible implementation, the processor is further configured to delay, by L symbols, sending of a data stream output through each lane with an odd sequence number in the a data streams, where L is equal to 136*N+1, and N is an integer greater than or equal to 1.

In a possible implementation, a is equal to 16, b is equal to 2, a quantity of symbols included in the symbol group is 2, and any eight consecutive symbol groups included in any one of the b data streams respectively come from eight data streams in the a data streams.

In a possible implementation, the processor is further configured to delay, by L symbols, sending of a data stream output through each lane with an odd sequence number in the a data streams, where L is equal to 68*N+1, and N is an integer greater than or equal to 1.

In a possible implementation, a is equal to 16, b is equal to 8, a quantity of symbols included in the symbol group is 4, and any two consecutive symbol groups included in any one of the b data streams respectively come from two data streams in the a data streams.

In a possible implementation, an order of codewords to which consecutive symbols output through any lane with an even sequence number in the a data streams belong is the same as an order of codewords to which consecutive symbols output through any lane with an odd sequence number in the a data streams belong.

In a possible implementation, a is equal to 32, b is equal to 4, a quantity of symbols included in the symbol group is 2, and any eight consecutive symbol groups included in any one of the b data streams respectively come from eight data streams in the a data streams, where the eight data streams in the a data streams include four data streams from a first codeword group and four data streams from a second codeword group, the first codeword group includes two codewords, the second codeword group includes two codewords, and the two codewords included in the first codeword group are different from the two codewords included in the second codeword group.

In a possible implementation, the processor is further configured to delay, by L symbols, sending of a data stream output through each lane with an odd sequence number in the a data streams, where L is equal to 2*N+1, and N is an integer greater than or equal to 0.

In a possible implementation, the processor is further configured to: encode received data to obtain K codeword groups, where K is an integer greater than or equal to 1, and a quantity of symbols included in any codeword in the K codeword groups is a positive integer multiple of 544; and interleave, based on the symbol, codewords included in the K codeword groups, to obtain the a data streams.

In a possible implementation, the encoding includes forward error correction FEC encoding.

In a possible implementation, a sum of rates of the a data streams is the same as a sum of rates of the b data streams.

In a possible implementation, a rate of any one of the b data streams is 200 Gbps.

According to a fourth aspect, a data receiving apparatus is provided. The apparatus includes a processor and a receiver coupled to the processor. The receiver is configured to receive b data streams, where b is an integer greater than or equal to 1, any one of the b data streams includes a plurality of symbol groups, any symbol group includes a plurality of symbols from different codewords, and any symbol includes a plurality of bits. The processor is configured to demultiplex the b data streams based on the symbol group to obtain a data streams, where a is an integer greater than or equal to 2, and a>b.

In a possible implementation, the a data streams include a first data stream and a second data stream, the b data streams include a third data stream, the plurality of symbol groups include a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

In a possible implementation, the a data streams are based on RS encoding, and the symbol is an RS symbol.

In a possible implementation, a length of the RS symbol is 10 bits.

According to a fifth aspect, a data processing apparatus is provided. The apparatus includes a unit configured to perform the method according to any one of the first aspect and the possible implementations of the first aspect, or a unit configured to perform the method according to any one of the second aspect and the possible implementations of the second aspect.

According to a sixth aspect, a data processing apparatus is provided. The apparatus includes a processor, and the processor is configured to implement the method according to any one of the first aspect and the possible implementations of the first aspect or the method according to any one of the second aspect and the possible implementations of the second aspect.

In a possible implementation, the apparatus further includes a memory, and the memory is configured to store computer-executable instructions. When the processor executes the computer-executable instructions in the memory, the apparatus is triggered to implement the method according to any one of the first aspect and the possible implementations of the first aspect or the method according to any one of the second aspect and the possible implementations of the second aspect.

According to a seventh aspect, a computer-readable storage medium is provided. The computer-readable storage medium stores instructions. When the instructions are run on a computer, the computer is enabled to perform the method according to any one of the first aspect and the possible implementations of the first aspect or the method according to any one of the second aspect and the possible implementations of the second aspect.

According to an eighth aspect, a computer program product is provided. The computer program product stores instructions. When the instructions are run on a computer, the computer is enabled to perform the method according to any one of the first aspect and the possible implementations of the first aspect or the method according to any one of the second aspect and the possible implementations of the second aspect.

According to a ninth aspect, a chip is provided. The chip may include a processing circuit or an interface circuit. When the chip is run, the method according to any one of the first aspect and the possible implementations of the first aspect or the method according to any one of the second aspect and the possible implementations of the second aspect is implemented.

According to a tenth aspect, a system is provided. The system includes a transmitting end and a receiving end. The transmitting end includes the apparatus according to any one of the third aspect or the possible implementations of the third aspect, and the receiving end includes the apparatus according to any one of the fourth aspect or the possible implementations of the fourth aspect. A device at the transmitting end and a device at the receiving end each include a host chip; the device at the transmitting end and the device at the receiving end each include a host chip, a clock and data recovery (CDR) chip, and an optical module; the device at the transmitting end and the device at the receiving end each include a host chip and an optical module; the device at the transmitting end includes a host chip, a CDR chip, and an optical module, and the device at the receiving end includes a host chip and an optical module; or the device at the transmitting end includes a host chip and an optical module, and the device at the receiving end includes a host chip, a CDR chip, and an optical module.

According to an eleventh aspect, a data processing method is provided. The method includes: performing first data processing on received first data, to obtain second data; distributing the second data based on a data block, to obtain a first data stream and a second data stream; performing FEC encoding on the first data stream, to obtain a first codeword and a second codeword; performing FEC encoding on the second data stream, to obtain a third codeword and a fourth codeword; and interleaving and distributing the first codeword, the second codeword, the third codeword, and the fourth codeword based on a symbol, to obtain a data streams, where a is an integer greater than 1.

In a possible implementation, after the a data streams are obtained, the method further includes steps included in the method according to any one of the first aspect or the possible implementations of the first aspect.

In a possible implementation, the method according to any one of the first aspect or the possible implementations of the first aspect is implemented by a PMA layer.

In a possible implementation, the step of obtaining the second data stream to the step of obtaining the a data streams are implemented by a physical coding sublayer (PCS).

In a possible implementation, the first data processing includes transcoding from 64B/66B to 256B/257B, and the first data is data obtained through 64B/66B encoding, where B represents a bit block.

In a possible implementation, the first codeword and the second codeword come from a same encoder, and the third codeword and the fourth codeword come from a same encoder.

In a possible implementation, a is 16, and four consecutive symbols in any one of the a data streams respectively come from the first codeword, the second codeword, the third codeword, and the fourth codeword.

In a possible implementation, a is 16, and a rate of any one of the a data streams is 100 Gbps.

In a possible implementation, codewords included in a codeword group are obtained by performing encoding by a same encoder.

In a possible implementation, the method is implemented by a chip or an optical module at a transmitting end.

In a possible implementation, the data block is 257 bits (b).

According to a twelfth aspect, a data processing method is provided. The method is a method obtained through reverse running of the method according to the eleventh aspect. The method is implemented by a chip or an optical module at a receiving end.

According to a thirteenth aspect, a data sending apparatus is provided. The apparatus includes a processor, and the processor is configured to: perform first data processing on received first data, to obtain second data; distribute the second data based on a data block, to obtain a first data stream and a second data stream; perform FEC encoding on the first data stream, to obtain a first codeword and a second codeword; perform FEC encoding on the second data stream, to obtain a third codeword and a fourth codeword; and interleave and distribute the first codeword, the second codeword, the third codeword, and the fourth codeword based on a symbol, to obtain a data streams, where a is an integer greater than 1.

In a possible implementation, the processor is further configured to perform a step included in the method according to any one of the first aspect or the possible implementations of the first aspect.

In a possible implementation, the method according to any one of the first aspect or the possible implementations of the first aspect is implemented by a PMA layer included in the processor.

In a possible implementation, the step of obtaining the second data stream to the step of obtaining the a data streams are implemented by a PCS included in the processor.

In a possible implementation, the first data processing includes transcoding from 64B/66B to 256B/257B, and the first data is data obtained through 64B/66B encoding, where B represents a bit block.

In a possible implementation, the first codeword and the second codeword come from a same encoder included in the processor, and the third codeword and the fourth codeword come from a same encoder included in the processor.

In a possible implementation, a is 16, and four consecutive symbols in any one of the a data streams respectively come from the first codeword, the second codeword, the third codeword, and the fourth codeword.

In a possible implementation, a is 16, and a rate of any one of the a data streams is 100 Gbps.

In a possible implementation, codewords included in a codeword group are obtained by performing encoding by a same encoder included in the processor.

In a possible implementation, the processor is located on a chip or an optical module at a transmitting end.

In a possible implementation, the data block is 257 b.

According to a fourteenth aspect, a data receiving apparatus is provided. The data receiving apparatus includes a processor, and the processor is configured to perform a method obtained through reverse running of the method according to the eleventh aspect. The processor is located on a chip or an optical module at a receiving end.

According to a fifteenth aspect, a data processing method is provided. The method includes: encoding received first data, to obtain second data; distributing the second data based on a data block, to obtain a first data stream and a second data stream; performing first data processing and FEC encoding on the first data stream, to obtain a first codeword and a second codeword; performing first data processing and FEC encoding on the second data stream, to obtain a third codeword and a fourth codeword; and interleaving and distributing the first codeword, the second codeword, the third codeword, and the fourth codeword based on a symbol, to obtain a data streams, where a is an integer greater than 1.

In a possible implementation, after the a data streams are obtained, the method further includes steps included in the method according to any one of the first aspect or the possible implementations of the first aspect.

In a possible implementation, the method according to any one of the first aspect or the possible implementations of the first aspect is implemented by a PMA layer.

In a possible implementation, the step of obtaining the second data stream to the step of obtaining the a data streams are implemented by a PCS.

In a possible implementation, the first data processing includes transcoding from 64B/66B to 256B/257B, and the second data is data obtained through 64B/66B encoding, where B represents a bit block.

In a possible implementation, the first codeword and the second codeword come from a same encoder, and the third codeword and the fourth codeword come from a same encoder.

In a possible implementation, a is 32, two consecutive symbols in any one of the a data streams come from a same codeword group, and the codeword group includes the first codeword and the second codeword, or the codeword group includes the third codeword and the fourth codeword.

In a possible implementation, a is 32, and a rate of any one of the a data streams is 25 Gbps.

In a possible implementation, codewords included in a codeword group are obtained by performing encoding by a same encoder.

In a possible implementation, the method is implemented by a chip or an optical module at a transmitting end.

In a possible implementation, the data block is 66 b.

According to a sixteenth aspect, a data processing method is provided. The method is a method obtained through reverse running of the method according to the fifteenth aspect. The method is implemented by a chip or an optical module at a receiving end.

According to a seventeenth aspect, a data sending apparatus is provided. The apparatus includes a processor, and the processor is configured to: encode received first data, to obtain second data; distribute the second data based on a data block, to obtain a first data stream and a second data stream; perform first data processing and FEC encoding on the first data stream, to obtain a first codeword and a second codeword; perform first data processing and FEC encoding on the second data stream, to obtain a third codeword and a fourth codeword; and interleave and distribute the first codeword, the second codeword, the third codeword, and the fourth codeword based on a symbol, to obtain a data streams, where a is an integer greater than 1.

In a possible implementation, the processor is further configured to perform a step included in the method according to any one of the first aspect or the possible implementations of the first aspect.

In a possible implementation, the method according to any one of the first aspect or the possible implementations of the first aspect is implemented by a PMA layer included in the processor.

In a possible implementation, the step of obtaining the second data stream to the step of obtaining the a data streams are implemented by a PCS included in the processor.

In a possible implementation, the first data processing includes transcoding from 64B/66B to 256B/257B, and the second data is data obtained through 64B/66B encoding, where B represents a bit block.

In a possible implementation, the first codeword and the second codeword come from a same encoder included in the processor, and the third codeword and the fourth codeword come from a same encoder.

In a possible implementation, a is 32, two consecutive symbols in any one of the a data streams come from a same codeword group, and the codeword group includes the first codeword and the second codeword, or the codeword group includes the third codeword and the fourth codeword.

In a possible implementation, a is 32, and a rate of any one of the a data streams is 25 Gbps.

In a possible implementation, codewords included in a codeword group are obtained by performing encoding by a same encoder included in the processor.

In a possible implementation, the processor is disposed on a chip or an optical module at a transmitting end.

In a possible implementation, the data block is 66 b.

According to an eighteenth aspect, a data receiving apparatus is provided. The apparatus includes a processor, and the processor is configured to perform a method obtained through reverse running of the method according to the fifteenth aspect. The processor is located on a chip or an optical module at a receiving end.

### BRIEF DESCRIPTION OF THE DRAWINGS

FIG. 1A is a diagram of data processing at a transmitting end;

FIG. 1B is a diagram of data processing at a receiving end;

FIG. 2 is a schematic flowchart of a data processing method according to an embodiment;

FIG. 3A is a diagram of interleaving and shifting two codewords included in one codeword group according to an embodiment;

FIG. 3B is a diagram of multiplexing data streams obtained through the shifting in FIG. 3A to obtain one data stream according to an embodiment;

FIG. 4A is a diagram of interleaving and shifting two codewords included in one codeword group according to an embodiment;

FIG. 4B is a diagram of multiplexing data streams obtained through the shifting in FIG. 4A to obtain two data streams according to an embodiment;

FIG. 5A and FIG. 5B are a diagram of interleaving and shifting a plurality of codewords included in two codeword groups according to an embodiment;

FIG. 5C and FIG. 5D are a diagram of multiplexing data streams obtained through the shifting in FIG. 5A and FIG. 5B to obtain four data streams according to an embodiment;

FIG. 6 is a diagram of multiplexing four codewords included in one codeword group according to an embodiment;

FIG. 7 is a schematic flowchart of another data processing method according to an embodiment;

FIG. 8A is a diagram of demultiplexing one multiplexed data stream according to an embodiment;

FIG. 8B is a diagram of shifting data streams obtained through the demultiplexing in FIG. 8A according to an embodiment;

FIG. 9A is a diagram of demultiplexing two multiplexed data streams according to an embodiment;

FIG. 9B and FIG. 9C are a diagram of shifting data streams obtained through the demultiplexing in FIG. 9A according to an embodiment;

FIG. 10A and FIG. 10B are a diagram of demultiplexing four multiplexed data streams according to an embodiment;

FIG. 10C and FIG. 10D are a diagram of shifting data streams obtained through the demultiplexing in FIG. 10A and FIG. 10B according to an embodiment;

FIG. 11 is a diagram of demultiplexing eight multiplexed data streams according to an embodiment;

FIG. 12A is a diagram of a structure of hardware according to an embodiment;

FIG. 12B is a diagram of a structure of other hardware according to an embodiment;

FIG. 13A is a diagram in which a data processing method is implementing by one chip according to an embodiment;

FIG. 13B is a diagram in which a data processing method is implementing by one chip according to an embodiment;

FIG. 13C is a diagram in which a data processing method is implementing by one chip according to an embodiment;

FIG. 14A is a diagram in which a data processing method is implemented by a plurality of chips according to an embodiment;

FIG. 14B is a diagram in which a data processing method is implemented by a plurality of chips according to an embodiment;

FIG. 14C is a diagram in which a data processing method is implemented by a plurality of chips according to an embodiment;

FIG. 14D is a diagram in which a data processing method is implemented by a plurality of chips according to an embodiment;

FIG. 14E is a diagram in which a data processing method is implemented by a plurality of chips according to an embodiment;

FIG. 14F is a diagram in which a data processing method is implemented by a plurality of chips according to an embodiment;

FIG. 15A is a diagram of a structure of a data sending apparatus according to an embodiment;

FIG. 15B is a diagram of a structure of a data receiving apparatus according to an embodiment;

FIG. 16A is a diagram of a structure of another data sending apparatus according to an embodiment;

FIG. 16B is a diagram of a structure of another data receiving apparatus according to an embodiment;

FIG. 17 is a diagram of a structure of a data processing apparatus according to an embodiment; and

FIG. 18 is a diagram of a structure of a data processing system according to an embodiment.

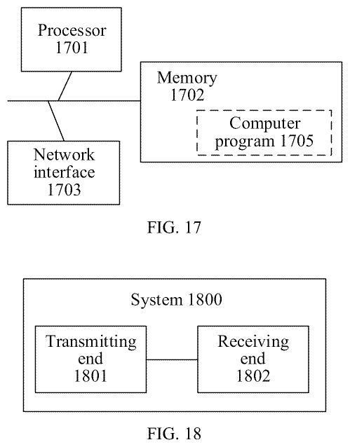

### DETAILED DESCRIPTION

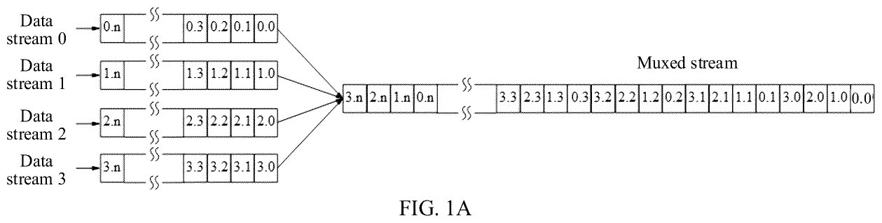

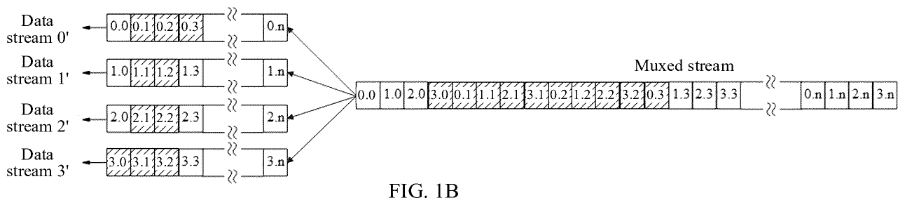

To facilitate data processing or reduce costs, a chip, a unit, or a module usually performs data processing on a plurality of low-rate data streams, to obtain one or more high-rate data streams. The data processing may include a possible manner, for example, mapping, multiplexing, interleaving, or combining. The one or more high-rate data streams may be transmitted through an optical fiber or another medium. FIG. 1A provides a data processing manner of a transmitting end. In FIG. 1A, the transmitting end uses a multiplexing data processing manner, in other words, performs multiplexing at a granularity of a bit. The transmitting end combines a plurality of low-rate data streams into one high-rate data stream. In FIG. 1A, each grid represents 1-bit data of a data stream from the transmitting end, X in X.Y marked by each grid represents data stream X, and Y represents bit Y. FIG. 1A is described by using n+1 bits in each data stream as an example, where n is an integer greater than or equal to 0. As shown in FIG. 1A, data stream 0, data stream 1, data stream 2, and data stream 3 are all low-rate data streams. For example, a low rate is 25 Gbps. The transmitting end reads data of bit Y in each low-rate data stream in an order of data stream 0->data stream 1->data stream 2->data stream 3 as 4 bits that are sequentially output from an obtained high-rate data stream (a muxed stream shown in FIG. 1A). The transmitting end performs cyclic processing in the foregoing manner to obtain 4*(n+1)-bit data included in the muxed stream. A burst error, namely, a plurality of consecutive bit errors, may occur in a transmission process of the muxed stream in FIG. 1A. As shown in FIG. 1B, a muxed stream received by a receiving end includes a 10-bit burst error (grids with slashes in FIG. 1B), in other words, the burst error occurs in a transmission process in 10 bits numbered 3.0, 0.1, 1.1, 2.1, 3.1, 0.2, 1.2, 2.2, 3.2, and 0.3. The receiving end obtains four low-rate data streams, for example, data stream 0′, data stream 1′, data stream 2′, and data stream 3′, based on the muxed stream with a 10-bit burst error. The 10-bit burst error is spread to a plurality of symbols included in data stream 0′, data stream 1′, data stream 2′, and data stream 3′ at the receiving end. For example, 0.1, 0.2, and 0.3 are symbols included in data stream 0′, 1.1 and 1.2 are symbols included in data stream 1′, 2.1 and 2.2 are symbols included in data stream 2′, and 3.0, 3.1, and 3.2 are symbols included in data stream 3′. In a bit mux-based processing manner of the transmitting end, a burst error in a transmission process is greatly spread to a plurality of symbols of a plurality of data streams. Because FEC codeword error correction can correct only a specific quantity of symbol errors, for example, when FEC codeword error correction corresponding to RS (544, 514) is used, a maximum of 15 symbol errors can be corrected. Once a quantity of symbol errors caused by burst error data generated in a transmission process that is based on bit multiplexing exceeds a quantity of correctable symbol errors, for example, exceeds 15 symbol errors, FEC codeword error correction fails, error correction performance is reduced, and a correctness percentage of subsequent data transmission is reduced; and consequently, system reliability is reduced.

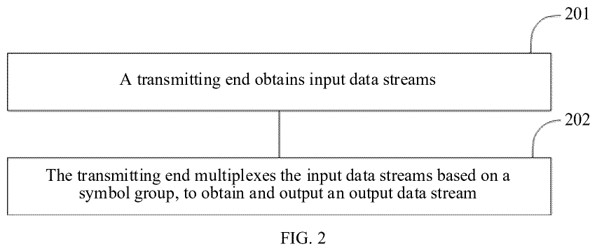

FIG. 2 is a schematic flowchart of a data processing method according to an embodiment. The method shown in FIG. 2 is performed by a transmitting end. The transmitting end may be a module or a chip that acts as a sending role. The module or the chip may be disposed in a host or an optical module. The host may be a router, a switch, a server, or the like.

201: The transmitting end obtains input data streams.

In a first possible implementation, the input data streams are data streams obtained by interleaving M codeword groups based on a symbol, where M is an integer greater than or equal to 1. The codeword group includes a plurality of codewords. The plurality of codewords included in the codeword group may be different codewords output by different encoders, or may be different codewords consecutively output by a same encoder. All symbols in any interleaved data stream come from one codeword group. Any two consecutive symbols in any interleaved data stream come from different codewords, in other words, two adjacent codewords come from different codewords in a same codeword group. In embodiments, “adjacent” means bits or symbols that are adjacent in locations and that are not spaced by another codeword. A length of the symbol is a plurality of bits. For example, the length of the symbol may be an integer multiple of 10 bits, and may be specifically 10 bits, 20 bits, or the like. Examples are not described one by one herein. The symbol may be an RS symbol, and a length of the RS symbol is 10 bits. The interleaving may be symbol-based multi-to-one interleaving, symbol-based multi-to-multi interleaving, or symbol-based single-to-single interleaving. The multi-to-one interleaving indicates that a plurality of data streams are interleaved into a single data stream. The multi-to-multi interleaving indicates that a plurality of data streams are interleaved into a plurality of data streams. The single-to-single interleaving indicates that a single data stream is still a single data stream through interleaving, and a change of the interleaved data stream compared with the data stream before the interleaving includes: An order of outputting a minimum data unit in a unit of a symbol is regularly adjusted. For example, a sending order of a first data unit and a second data unit that are included in the data stream before the interleaving is exchanged to form the interleaved data stream.

In a second possible implementation, the input data streams are data streams obtained through interleaving and shifting. The interleaving is interleaving the M codeword groups based on the symbol in the first possible implementation. Details are not described herein again. The shifting is delaying, by N bits, one or more data streams from a same codeword group in the interleaved data stream, so that symbols at same locations in any two data streams from the same codeword group come from a same codeword, where N is an integer greater than or equal to 1. For example, the N bits may be a length of one or more symbols. From a perspective of a sequence number of a lane, a specific shifting operation may be delaying, by the N bits, sending of a data stream transmitted through a lane with an even sequence number in a plurality of lanes for transmitting the input data streams; or delaying, by N bits, sending of data transmitted through a lane with an odd sequence number in a plurality of lanes for transmitting the input data streams. From a perspective of a codeword group, if data streams, of the input data streams, that are transmitted through a plurality of lanes come from a same codeword group, a specific shifting operation may be delaying sending of one or more lanes on which data streams having a same symbol order are located; or if data streams, of the input data streams, that are transmitted through a plurality of lanes come from different codeword groups, a specific shifting operation may be delaying sending of one or more lanes on which data streams from a same codeword group are located, or a specific shifting operation may be delaying sending of one or more lanes on which data streams that come from a same codeword group and that have a same symbol order are located.

In a third possible implementation, the input data streams are data streams obtained through encoding and interleaving. A code type of the encoding may be an RS code, a Bose-Chaudhuri-Hocquenghem (BCH) code, a Hamming code, or a low-density parity check (LDPC) code, a polar code, a convolutional code, a turbo code, a turbo product code (TPC), a staircase code, a fire code, a Reed-Muller (RM) code, or an Open FEC (oFEC) code. When the code type of the encoding is an RS code, a symbol included in a codeword obtained through the encoding is an RS symbol. For details, refer to related descriptions in the first possible implementation. The interleaving is interleaving the M codeword groups based on the symbol in the first possible implementation. Details are not described herein again.

In a fourth possible implementation, the input data streams are data streams obtained through encoding, interleaving, and shifting. The encoding is the encoding manner in the third possible implementation. The interleaving is interleaving the M codeword groups based on the symbol in the first possible implementation. The shifting is the shifting manner in the second possible implementation. Details of the foregoing manners are not described herein again.

202: The transmitting end multiplexes the input data streams based on a symbol group, to obtain and output an output data stream.

For example, any symbol group in the input data stream includes a plurality of symbols, the plurality of symbols included in the any symbol group come from a plurality of codewords, and the codewords from which the plurality of symbols in the any symbol group come are sorted in a same order. For 200GBASE-R and 400GBASE-R, any symbol group of the input data stream includes two symbols, and the two symbols come from different codewords in a same codeword group. Codewords from which symbols output from input data streams through lanes with odd sequence numbers come are sorted in a same order, codewords from which symbols output from input data streams through lanes with even sequence numbers come are sorted in a same order, and an order of codewords from which symbols output through any lane with an odd sequence number come is different from an order of codewords from which symbols output through any lane with an even sequence number come. For 800GBASE-R, any symbol group of the input data stream includes two symbols, and the two symbols come from different codewords in a same codeword group. The input data stream outputs, through a plurality of lanes, symbols that come from a first codeword group, and outputs, through a plurality of other lanes, symbols that come from a second codeword group. Codewords from which symbols output through lanes with odd sequence numbers in the plurality of lanes for outputting the symbols from the first codeword group come are sorted in a same order. Codewords from which symbols output through lanes with even sequence numbers in the plurality of lanes for outputting the symbols from the first codeword group come are sorted in a same order. An order of codewords from which symbols output through any lane with an odd sequence number in the plurality of lanes for outputting the symbols from the first codeword group come is different from an order of codewords from which symbols output through any lane with an even sequence number in the plurality of lanes for outputting the symbols from the first codeword group come. Codewords from which symbols output through lanes with odd sequence numbers in the plurality of lanes for outputting the symbols from the second codeword group come are sorted in a same order. Codewords from which symbols output through lanes with even sequence numbers in the plurality of lanes for outputting the symbols from the second codeword group come are sorted in a same order. An order of codewords from which symbols output through any lane with an odd sequence number in the plurality of lanes for outputting the symbols from the second codeword group come is different from an order of codewords from which symbols output through any lane with an even sequence number in the plurality of lanes for outputting the symbols from the second codeword group come. For 1.6TBASE-R, any symbol group of the input data stream includes four symbols, and the four symbols come from different codewords in a same codeword group. Codewords from which symbols output from the input data streams through any two lanes come are sorted in a same order.

For example, the transmitting end may obtain the output data stream in a round-robin manner. The input data streams may be transmitted through a plurality of lanes, for example, a lanes. The output data stream may also be transmitted through one or more lanes, for example, b lanes. a is an integer greater than or equal to 2, b is an integer greater than or equal to 1, and b<a. A sum of rates of data output through the a lanes is the same as a sum of rates of data output through the b lanes. For example, for 200GBASE-R, 400GBASE-R, or 800GBASE-R, an accurate value of a rate of data output through each of the a lanes is 26.5625 Gbps. In this case, a sum of rates of eight data streams at 26.5625 Gbps is 212.5 Gbps. After the data streams are multiplexed into one lane, an accurate value of a rate of data output through the lane is 212.5 Gbps. Generally, a rate of data output through each of the a lanes is roughly estimated to be 25 Gbps. In this case, a sum of rates of eight data streams at 25 Gbps is 200 Gbps. After the eight data streams are multiplexed into one lane, a rate of data output through the lane is 200 Gbps. For 1.6TBASE-R, two data streams in data streams output through the a lanes are combined into one data stream in data streams output through the b lanes, and an accurate value of a rate of data output through each of the a lanes is 106.25 Gbps. In this case, a sum of rates of the two data streams at 106.25 Gbps is 212.5 Gbps. After the two data streams are multiplexed into one lane, an accurate value of a rate of data output through the lane is 212.5 Gbps. Generally, a rate of data output through each of the a lanes is roughly estimated to be 100 Gbps. In this case, a sum of rates of two data streams at 100 Gbps is 200 Gbps. After the two data streams are multiplexed into one lane, an accurate value of a rate of data output through the lane is 200 Gbps. The a lanes or the b lanes may be logical lanes obtained through logical division, or may be physical lanes, for example, physical lanes corresponding to pins of a chip. The transmitting end may obtain, in a round-robin order, a plurality of consecutive symbols on each of the plurality of lanes for transmitting the input data streams, and map the obtained plurality of consecutive symbols on each lane as a symbol group to one lane for transmitting the output data stream. Two adjacent symbol groups in a data stream transmitted through any one of the one or more lanes for the output data stream come from different lanes for the input data streams. When the transmitting end performs round-robin, each time round-robin is performed on the plurality of lanes for the input data stream, this is considered as one cycle, and in each cycle, round-robin is performed on symbol groups at same locations in data streams transmitted through the lanes.

For example, the round-robin order may satisfy any one of the following: 1) round-robin is first performed on a data stream transmitted through a lane with an even sequence number, and then round-robin is performed on a data stream transmitted through a lane with an odd sequence number; 2) round-robin is first performed on a data stream transmitted through a lane with an odd sequence number, and then round-robin is performed on a data stream transmitted through a lane with an even sequence number; 3) round-robin is performed on data streams transmitted through the lanes in ascending or descending order of sequence numbers; 4) the lanes are classified into two parts based on sequence numbers, where the first part and the second part include a same quantity of lanes; and round-robin is first performed on a data stream transmitted through a lane with an even sequence number in the first part and a data stream transmitted through a lane with an odd sequence number in the second part, and then round-robin is performed on a data stream transmitted through a lane with an odd sequence number in the first part and a data stream transmitted through a lane with an even sequence number in the second part; or 5) the lanes are classified into two parts based on sequence numbers, where the first part and the second part include a same quantity of lanes; and round-robin is first performed on a data stream transmitted through a lane with an odd sequence number in the first part and a data stream transmitted through a lane with an even sequence number in the second part, and then round-robin is performed on a data stream transmitted through a lane with an even sequence number in the first part and a data stream transmitted through a lane with an odd sequence number in the second part.

In a possible implementation of the foregoing round-robin order, when round-robin is performed on data streams transmitted through some lanes in the first part and data streams transmitted through some lanes in the second part, round-robin may be first performed on the data streams transmitted through the some lanes in the first part, and then round-robin may be performed on the data streams transmitted through the some lanes in the second part. Alternatively, when round-robin is performed on data streams transmitted through some lanes in the first part and data streams transmitted through some lanes in the second part, round-robin may be performed on a data stream transmitted through one lane in the first part, and then round-robin is performed on a data stream transmitted through one lane in the second part; round-robin continues to be performed on a data stream transmitted through another lane in the first part, and then round-robin is performed on a data stream transmitted through another lane in the second part, until round-robin is performed on all of the data streams transmitted through the some lanes in the first part and the data streams transmitted through the some lanes in the second part.

In the method provided in this embodiment, the transmitting end performs multiplexing based on the symbol group including the symbols. In this way, even if a burst error of a plurality of consecutive bits occur in the obtained output data stream in a transmission process, after a receiving end performs demultiplexing based on the symbol group, the burst error of the plurality of consecutive bits affects only a small quantity of symbols, in other words, a quantity of symbols that are of the data stream multiplexed based on the symbol group and that are affected by the burst error of the plurality of consecutive bits is far less than a quantity of symbols that are of a data stream multiplexed based on a bit and that are affected by the burst error of the plurality of consecutive bits, so that error correction performance and system reliability are improved.

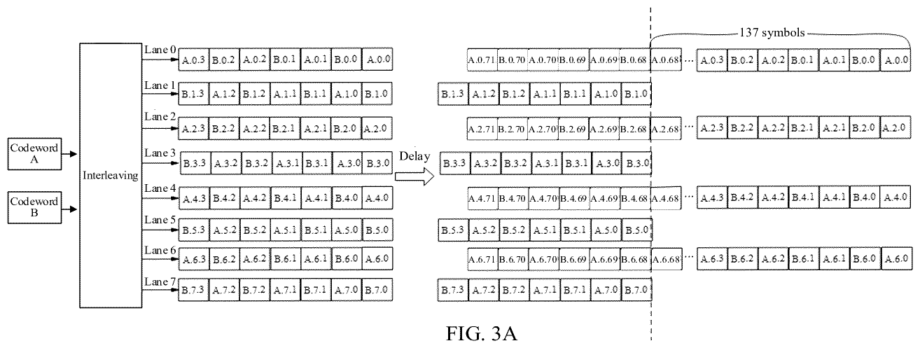

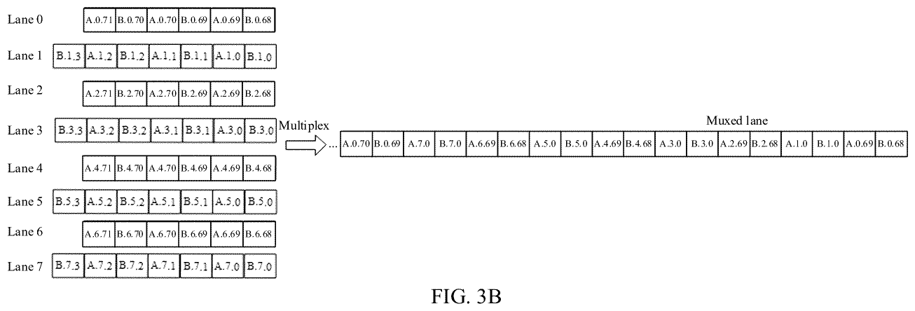

FIG. 3A and FIG. 3B are embodiments in which a codeword group includes two different codewords, a quantity of lanes for input data streams is 8, and a quantity of lanes for an output data stream is 1. For a codeword group including two different codewords, a method in this embodiment may also be used in another scenario in which a ratio of a quantity of lanes for input data streams to a quantity of lanes for an output data stream is 8:1. Examples are not described herein one by one.

FIG. 3A is a diagram of interleaving and shifting a plurality of codewords included in one codeword group. The codeword group in FIG. 3A includes codeword A and codeword B, and codeword A and codeword B come from different encoders. A minimum data unit included in codeword A and codeword B is a symbol. After symbol-based interleaving, pieces of data of codeword A and codeword B are output through eight lanes. The interleaving belongs to multi-to-multi interleaving, in other words, a plurality of codewords are interleaved to obtain a plurality of interleaved data streams. An identifier O.p.q in each block in FIG. 3A indicates that a current symbol belongs to codeword O, and a transmission sequence number in a lane with sequence number p is q. In this embodiment, data that is consecutively output through a lane is a data stream. For all symbols included in a codeword in a codeword group, for example, codeword A and codeword B each include 544 symbols, any two adjacent symbols on any one of lane 0 to lane 7 come from different codewords in a same codeword group, in other words, any two consecutive symbols on any lane come from different codewords in a same codeword group. In this embodiment, “adjacent” means that locations are adjacent without any spacing. For example, for two symbols A.1.0 and B.1.0 output through lane 1, A.1.0 and B.1.0 respectively come from codeword A and codeword B that are included in the codeword group, and A. 1.0 and B.1.0 are adjacent without any spacing on lane 1, in other words, A. 1.0 and B.1.0 are adjacent. When data from codeword A and codeword B is output through lane 1, two consecutive symbols A.1.0 and B.1.0 respectively come from codeword A and codeword B that are included in the codeword group. A quantity of symbols included in each of codeword A and codeword B after encoding is L₁*544, where L₁ is an integer greater than or equal to 1. After being interleaved, symbols included in each codeword are output through eight lanes: lane 0 to lane 7. A quantity of output symbols of each lane is L₁*136, where L₁*68 symbols come from codeword A, and L₁*68 symbols come from codeword B. Symbols that are of different codewords coming from the codeword group and that are output through lanes with even sequence numbers in lane 0 to lane 7 are sorted in a same order, symbols that are of different codewords coming from the codeword group and that are output through lanes with odd sequence numbers are sorted in a same order, and the order of the symbols output through the lanes with the even sequence numbers is different from the order of the symbols output through the lanes with the odd sequence numbers. For example, any two lanes with even sequence numbers are selected. Symbols included in lane 4 and lane 6 come from codeword A and codeword B that are included in the codeword group, symbols output through lane 4 after codeword A and codeword B are interleaved may be represented as: A.4.0->B.4.0->A.4.1->B.4.1->A.4.2->B.4.2->A.4.3-> . . . ->A.4.67->B.4.67. Symbols output through lane 6 after codeword A and codeword B are interleaved may be represented as: A.6.0->B.6.0->A.6.1->B.6.1->A.6.2->B.6.2->A.6.3-> . . . ->A.6.67->B.6.67. After codeword A and codeword B are interleaved, an order of the symbols output through lane 4 and an order of the symbols output through lane 6 are both an order of ABABAB. For example, any two lanes with odd sequence numbers are selected. Symbols included in lane 1 and lane 3 come from codeword A and codeword B that are included in the codeword group. Symbols output through lane 1 after codeword A and codeword B are interleaved may be represented as: B.1.0->A.1.0->B.1.1->A.1.1->B.1.2->A.1.2->B.1.3-> . . . >B.1.67->A.1.67, and symbols output through lane 3 after codeword A and codeword B are interleaved may be represented as: B.3.0->A.3.0->B.3.1->A.3.1->B.3.2->A.3.2->B.3.3-> . . . >B.3.67->A.3.67. After codeword A and codeword B are interleaved, an order of the symbols output through lane 1 and an order of the symbols output through lane 3 are both an order of BABABA. In this embodiment, some symbols are used as an example for description, and a quantity of symbols greater than that shown in the figure is not described by using an example. Based on FIG. 3A and the foregoing content, the symbols output through the lanes with the even sequence numbers and the symbols output through the lanes with the odd sequence numbers come from the same codeword group, but have different orders.

A transmitting end may shift an interleaved data stream. For example, in the scenario shown in FIG. 3A, sending of data output through each of four lanes, namely, lane 1, lane 3, lane 5, and lane 7 is delayed, and a depth of the delay is a length of an odd quantity of symbols, for example, a length of 137 symbols. When a length of an RS symbol is 10 bits, an operation of delaying, by 10 bits, sending of the data output through each of lane 1, lane 3, lane 5, and lane 7 is performed. Alternatively, if a length of an RS symbol is 10 bits, an operation of delaying, by 1370 bits, sending of the data output through each of lane 1, lane 3, lane 5, and lane 7 is performed. The transmitting end may also delay sending of data output through the lanes with the even sequence numbers. Examples are not described herein. The data is sent with the delay of the length of the odd quantity of symbols, orders of symbols output through any two lanes can be the same, and an interleaving depth can further be increased, to enhance an error correction capability for a burst error. For example, sending on each lane with an odd sequence number is delayed by 137 symbols. In this way, original multiplexing of 2*RS symbols may be converted into multiplexing of 4*RS symbols, in other words, any four symbols on the lane for transmitting the output data stream come from four different codewords, instead of that any four symbols come from two different codewords. For example, a same encoder encodes a codeword including 544 symbols each time. In four consecutive symbols B.0.68, A.0.69, B.1.0, and A.1.0 in a muxed lane after delayed sending, A.1.0 and A.0.69 are output through two times of encoding of a same encoder, and B.1.0 and B.0.68 are output through two times of encoding of a same encoder, in other words, the foregoing four symbols come from four different codewords. For example, sending on the lane with the odd sequence number is delayed by 137 symbols. A boundary of a symbol identified by B.1.0 on lane 1 on which the sending is delayed is aligned with a boundary of a symbol identified by B.0.68 on lane 0, and a boundary of a symbol identified by A.1.0 on lane 1 on which the sending is delayed is aligned with a boundary of a symbol identified by A.0.69 on lane 0. A boundary of a symbol identified by B.3.0 on lane 3 on which the sending is delayed is aligned with a boundary of a symbol identified by B.6.68 on lane 6, and a boundary of a symbol identified by A.3.0 on lane 3 on which the sending is delayed is aligned with a boundary of a symbol identified by A.6.69 on lane 6. A boundary of a symbol identified by B.5.0 on lane 5 on which the sending is delayed is aligned with a boundary of a symbol identified by B.2.68 on lane 2, and a boundary of a symbol identified by A.5.0 on lane 5 on which the sending is delayed is aligned with a boundary of a symbol identified by A.2.69 on lane 2. A boundary of a symbol identified by B.7.0 on lane 7 on which the sending is delayed is aligned with a boundary of a symbol identified by B.4.68 on lane 4, and a boundary of a symbol identified by A.7.0 on lane 7 on which the sending is delayed is aligned with a boundary of a symbol identified by A.4.69 on lane 4. An order of symbols output through any lane after the shifting is an order of BABABABA, and alignment manners of remaining symbols are not described herein by using examples one by one.

In another possible implementation, sending on the lanes with the even sequence numbers in lane 0 to lane 7 is delayed, and an order of symbols output through any one of lane 0 to lane 7 after the shifting is an order of ABABAB. A rule of delaying sending on the lanes with the even sequence numbers is similar to a rule of delaying sending on the lanes with the odd sequence numbers. For details, refer to related content in FIG. 3A. Details are not described herein again.

FIG. 3B is a diagram of multiplexing data streams obtained through the shifting in FIG. 3A to obtain one data stream. FIG. 3B is described by using an example in which a symbol group includes two symbols. The two symbols included in the symbol group respectively come from codeword B and codeword A. In this embodiment, a symbol group including two symbols may also be referred to as a symbol pair, or two symbols from different codewords are referred to as a symbol pair. Codewords from which symbols included in any symbol group in FIG. 3B come are sorted in a same order, which is an order of BA. To be specific, one symbol group is used as an example, and a symbol from codeword B is followed by a symbol from codeword A in the symbol group. In a process in which the transmitting end performs round-robin on lane 0 to lane 7 to obtain symbol groups, the transmitting end performs round-robin on each of the eight lanes in ascending order of sequence numbers in each cycle, to obtain a symbol group at a same location on each lane. Eight symbol groups obtained in one cycle are consecutively output to a muxed lane in an order of the sequence numbers of the lanes to which the symbol groups belong. In each cycle, processing is performed in the round-robin manner in the cycle, until round-robin is performed on all symbol groups output from the codeword group. A specific round-robin manner is described below by using two cycles as an example. A symbol group including B.0.68 and A.0.69 on lane 0, a symbol group including B.1.0 and A.1.0 on lane 1, a symbol group including B.2.68 and A.2.69 on lane 2, a symbol group including B.3.0 and A.3.0 on lane 3, a symbol group including B.4.68 and A.4.69 on lane 4, a symbol group including B.5.0 and A.5.0 on lane 5, a symbol group including B.6.68 and A.6.69 on lane 6, and a symbol group including B.7.0 and A.7.0 on lane 7 are respectively symbol groups at same locations in symbol groups of lane 0 to lane 7. The foregoing eight symbol groups are sequentially output through the muxed lane in an order of the sequence numbers of the lanes to which the eight symbol groups belong. For example, symbols that are sequentially output through the muxed lane may be represented as: B.0.68->A.0.69->B.1.0->A.1.0->B.2.68->A.2.69->B.3.0->A.3.0->B.4.68->A.4.69->B.5.0->A.5.0->B.6.68->A.6.69->B.7.0->A.7.0. A symbol group including B.0.69 and A.0.70 on lane 0, a symbol group including B.1.1 and A.1.1 on lane 1, a symbol group including B.2.69 and A.2.70 on lane 2, a symbol group including B.3.1 and A.3.1 on lane 3, a symbol group including B.4.69 and A.4.70 on lane 4, a symbol group including B.5.1 and A.5.1 on lane 5, a symbol group including B.6.69 and A.6.70 on lane 6, and a symbol group including B.7.1 and A.7.1 on lane 7 are symbol groups, at same locations, in the symbol groups output through lane 0 to lane 7. On the muxed lane, symbols that are included in the above eight symbol groups at other same locations and that are sequentially output after the symbol A.7.0 may be represented as: B.0.69->A.0.70->B.1.1->A.1.1->B.2.69->A.2.70->B.3.1->A.3.1->B.4.69->A.4.70->B.5.1->A.5.1->B.6.69->A.6.70->B.7.1->A.7.1. Any eight consecutive symbol groups in symbol groups output through the muxed lane come from eight different lanes.

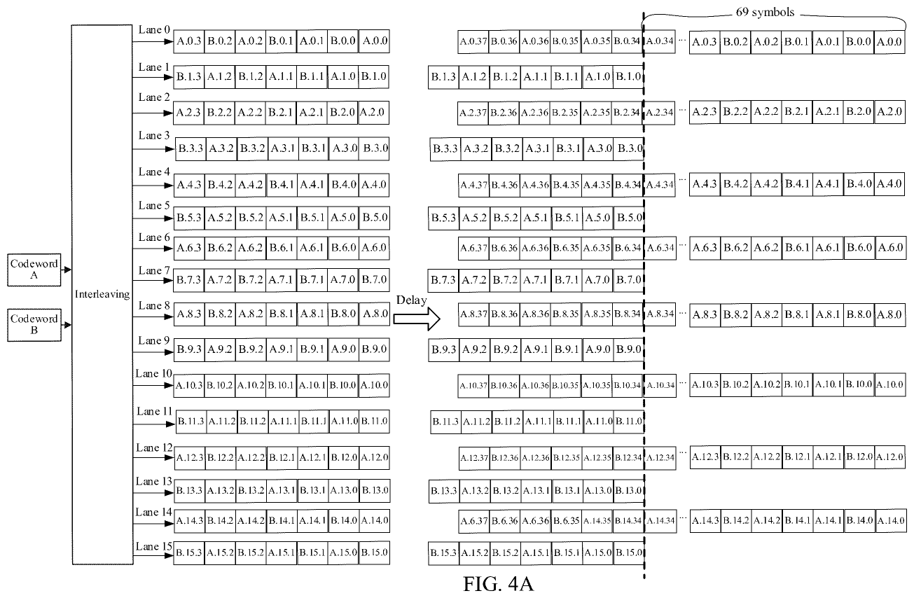

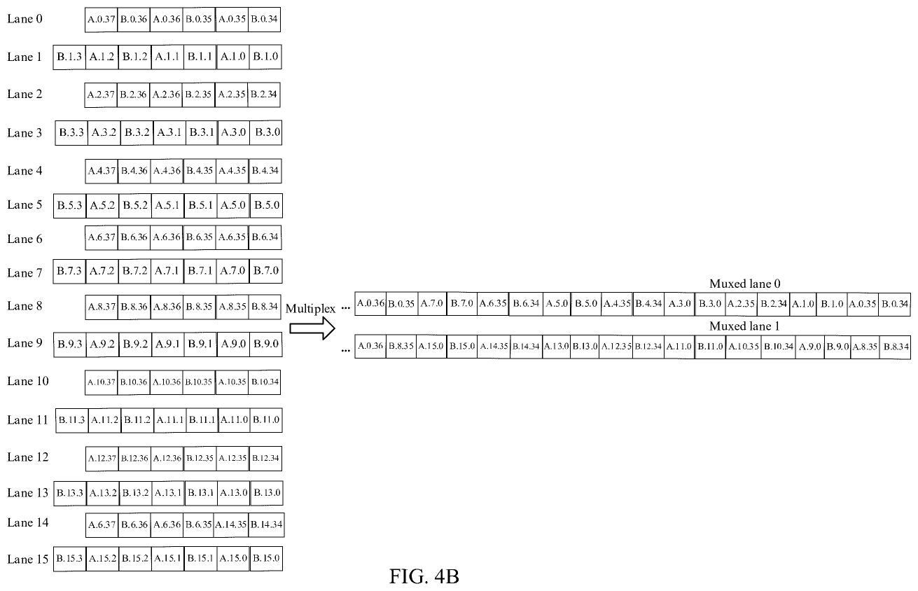

FIG. 4A and FIG. 4B are embodiments in which a codeword group includes two different codewords, a quantity of lanes for an input data stream is 16, and a quantity of lanes for an output data stream is 2. For a codeword group including two different codewords, a method in this embodiment may also be used in another scenario in which a ratio of a quantity of lanes for an input data stream to a quantity of lanes for an output data stream is 16:2. Examples are not described herein one by one.

FIG. 4A is a diagram of interleaving and shifting a plurality of codewords included in one codeword group. For meanings of the codeword group, a symbol, and an identifier in each block in FIG. 4A, refer to related descriptions in FIG. 3A. Any two adjacent symbols on any one of lane 0 to lane 15 come from different codewords in a same codeword group, in other words, any two consecutive symbols in any one of the lanes come from different codewords in a same codeword group. For meanings of “adjacent” and “consecutive” in FIG. 4A, refer to related descriptions in FIG. 3A. A quantity of symbols included in codeword A and codeword B in FIG. 4A is L₂*544, where L₂ is an integer greater than or equal to 1. After being interleaved, symbols included in each codeword are output through 16 lanes: lane 0 to lane 15. A quantity of output symbols of each lane is L₂*68, where L₂*34 symbols come from codeword A, and L₂*34 symbols come from codeword B. The interleaving belongs to multi-to-multi interleaving, in other words, a plurality of codewords are interleaved to obtain a plurality of data streams. Symbols that are of different codewords coming from the codeword group and that are output through lanes with even sequence numbers in lane 0 to lane 15 are sorted in a same order, symbols that are of different codewords coming from the codeword group and that are output through lanes with odd sequence numbers are sorted in a same order, and the order of the symbols output through the lane with the even sequence number is different from the order of the symbols output through the lane with the odd sequence number. For example, after codeword A and codeword B are interleaved, the order of the symbols output through the lane with the even sequence number is an order of ABABAB. After codeword A and codeword B are interleaved, the order of the symbols output through the odd sequence number is an order of BABABA. In this embodiment, some symbols are used as an example for description, and a quantity of symbols greater than that shown in the figure is not described by using an example.

A transmitting end may shift the interleaved streams. For example, data output through each of eight lanes, namely, lane 1, lane 3, lane 5, lane 7, lane 9, lane 11, lane 13, and lane 15 is sent after a delay, and a depth of the delay is a length of an odd number of symbols, for example, a length of 69 symbols. When a length of an RS symbol is 10 bits, sending of the data output through each of lane 1, lane 3, lane 5, lane 7, lane 9, lane 11, lane 13, and lane 15 is delayed by 10 bits. Alternatively, when a length of an RS symbol is 10 bits, sending of the data output through each of lane 1, lane 3, lane 5, lane 7, lane 9, lane 11, lane 13, and lane 15 is delayed by 690 bits. The data is sent with the delay of the odd quantity of symbols, orders of symbols output through any two lanes can be the same, and an interleaving depth can further be increased, to enhance an error correction capability for a burst error. For example, sending on each lane with an odd sequence number is delayed by 69 symbols. In this way, multiplexing of 2*RS symbols may be converted into multiplexing of 4*RS symbols, in other words, any four symbols on the lane for transmitting the output data stream come from four different codewords, instead of that any four symbols come from two different codewords. For example, a same encoder encodes a codeword including 544 symbols each time. In four consecutive symbols B.0.34, A.0.35, B.1.0, and A.1.0 in muxed lane 0 after delayed sending, A.1.0 and A.0.35 are output through two times of encoding of the same encoder, and B.1.0 and B.0.35 are output through two times of encoding of the same encoder, in other words, the foregoing four symbols come from four different codewords. For example, sending on the lane with the odd sequence number is delayed by 69 symbols. A boundary of a symbol identified by B.1.0 on lane 1 on which the sending is delayed is aligned with a boundary of a symbol identified by B.0.34 on lane 0, and a boundary of a symbol identified by A.1.0 on lane 1 on which the sending is delayed is aligned with a boundary of a symbol identified by A.0.35 on lane 0. A boundary of a symbol identified by B.3.0 on lane 3 on which the sending is delayed is aligned with a boundary of a symbol identified by B.6.34 on lane 6, and a boundary of a symbol identified by A.3.0 on lane 3 on which the sending is delayed is aligned with a boundary of a symbol identified by A.6.35 on lane 6. A boundary of a symbol identified by B.5.0 on lane 5 on which the sending is delayed is aligned with a boundary of a symbol identified by B.2.34 on lane 2, and a boundary of a symbol identified by A.5.0 on lane 5 on which the sending is delayed is aligned with a boundary of a symbol identified by A.2.35 on lane 2. A boundary of a symbol identified by B.7.0 on lane 7 on which the sending is delayed is aligned with a boundary of a symbol identified by B.12.34 on lane 12, and a boundary of a symbol identified by A.7.0 on lane 7 on which the sending is delayed is aligned with a boundary of a symbol identified by A.12.35 on lane 12. A boundary of a symbol identified by B.11.0 on lane 11 on which the sending is delayed is aligned with a boundary of a symbol identified by B.4.34 on lane 4, and a boundary of a symbol identified by A.11.0 on lane 11 on which the sending is delayed is aligned with a boundary of a symbol identified by A.4.35 on lane 4. A boundary of a symbol identified by B. 13.0 on lane 13 on which the sending is delayed is aligned with a boundary of a symbol identified by B.10.34 on lane 10, and a boundary of a symbol identified by A. 13.0 on lane 13 on which the sending is delayed is aligned with a boundary of a symbol identified by A.10.35 on lane 10. A boundary of a symbol identified by B.15.0 on lane 15 on which the sending is delayed is aligned with a boundary of a symbol identified by B.8.34 on lane 8, and a boundary of a symbol identified by A. 15.0 on lane 15 on which the sending is delayed is aligned with a boundary of a symbol identified by A.8.35 on lane 8. A boundary of a symbol identified by B.9.0 on lane 9 on which the sending is delayed is aligned with a boundary of a symbol identified by B.14.34 on lane 14, and a boundary of a symbol identified by A.9.0 on lane 9 on which the sending is delayed is aligned with a boundary of a symbol identified by A. 14.35 on lane 14. An order of symbols output through any lane after the shifting is an order of BABABABA, and alignment manners of remaining symbols are not described herein by using examples one by one.

In another possible implementation, sending on the lane with the even sequence number in lane 0 to lane 15 is delayed, and an order of symbols output through any one of lane 0 to lane 15 after the shifting is an order of ABABAB. A rule of delaying sending on the lane with the even sequence number is similar to a rule of delaying sending on the lane with the odd sequence number. For details, refer to related content in FIG. 4A. Details are not described herein again.

FIG. 4B is a diagram of multiplexing data streams obtained through the shifting in FIG. 4A to obtain two data streams. FIG. 4B is described by using an example in which a symbol group includes two symbols. The two symbols included in the symbol group respectively come from codeword B and codeword A. Codewords from which symbols included in any symbol group in FIG. 4B come are sorted in a same order, which is an order of BA. To be specific, a symbol from codeword B is followed by a symbol from codeword A in the symbol group. In a process in which the transmitting end performs round-robin on lane 0 to lane 15 to obtain symbol groups, lane 0 to lane 15 may be divided into two parts: lane 0 to lane 7 and lane 8 to lane 15. For each part, round-robin is performed on each of the eight lanes in ascending order of the sequence numbers in each cycle, to obtain a symbol group at a same location on each lane. Eight symbol groups obtained in one cycle are consecutively output to one muxed lane in an order of sequence numbers of lanes to which the symbol groups belong. For example, symbol groups of lane 0 to lane 7 are output through muxed lane 0, and symbol groups of lane 8 to lane 15 are output through muxed lane 1. In each cycle, processing is performed in the round-robin manner in the cycle, until round-robin is performed on all the symbol groups of the part.

A specific round-robin manner is described below by using two cycles as an example. For symbol groups output through lane 0 to lane 7, a symbol group including B.0.34 and A.0.35 on lane 0, a symbol group including B.1.0 and A.1.0 on lane 1, a symbol group including B.2.34 and A.2.35 on lane 2, a symbol group including B.3.0 and A.3.0 on lane 3, a symbol group including B.4.34 and A.4.35 on lane 4, a symbol group including B.5.0 and A.5.0 on lane 5, a symbol group including B.6.34 and A.6.35 on lane 6, and a symbol group including B.7.0 and A.7.0 on lane 7 are respectively symbol groups, at a same location, in the symbol groups output through lane 0 to lane 7. The foregoing eight symbol groups are sequentially output through muxed lane 0 in an order of the sequence numbers of the lanes to which the eight symbol groups belong. For example, symbols that are sequentially output through muxed lane 0 may be represented as: B.0.34->A.0.35->B.1.0->A.1.0->B.2.34->A.2.35->B.3.0->A.3.0->B.4.34->A.4.35->B.5.0->A.5.0->B.6.34->A.6.35->B.7.0->A.7.0. A symbol group including B.0.35 and A.0.36 on lane 0, a symbol group including B.1.1 and A.1.1 on lane 1, a symbol group including B.2.35 and A.2.36 on lane 2, a symbol group including B.3.1 and A.3.1 on lane 3, a symbol group including B.4.35 and A.4.36 on lane 4, a symbol group including B.5.1 and A.5.1 on lane 5, a symbol group including B.6.35 and A.6.36 on lane 6, and a symbol group including B.7.1 and A.7.1 on lane 7 are symbol groups, at a same location, in the symbol groups output through lane 0 to lane 7. On muxed lane 0, symbols that are included in eight symbol groups at other same locations and that are sequentially output after the symbol A.7.0 may be represented as: B.0.35->A.0.36->B.1.1->A.1.1->B.2.35->A.2.36->B.3.1->A.3.1->B.4.35->A.4.36->B.5.1->A.5.1->B.6.35->A.6.36->B.7.1->A.7.1. Any eight consecutive symbol groups in symbol groups output through muxed lane 0 come from eight different lanes: lane 0 to lane 7. For symbol groups output through lane 8 to lane 15, a symbol group including B.8.34 and A.8.35 on lane 8, a symbol group including B.9.0 and A.9.0 on lane 9, a symbol group including B.10.34 and A. 10.35 on lane 10, a symbol group including B.11.0 and A. 11.0 on lane 11, a symbol group including B.12.34 and A. 12.35 on lane 12, a symbol group including B.13.0 and A.13.0 on lane 13, a symbol group including B. 14.34 and A.14.35 on lane 14, and a symbol group including B.15.0 and A.15.0 on lane 15 are respectively symbol groups, at a same location, in the symbol groups output through lane 8 to lane 15. The foregoing eight symbol groups are sequentially output through muxed lane 1 in an order of the sequence numbers of the lanes to which the eight symbol groups belong. For example, symbols that are sequentially output through muxed lane 1 may be represented as: B.8.34->A.8.35->B.9.0->A.9.0->B.10.34->A.10.35->B.11.0->A.11.0->B.12.34->A.12.35->B.13.0->A.13.0->B.14.34->A.14.35->B.15.0->A.15.0. A symbol group including B.8.35 and A.8.36 on lane 8, a symbol group including B.9.1 and A.9.1 on lane 9, a symbol group including B.10.35 and A. 10.36 on lane 10, a symbol group including B.11.1 and A.11.1 on lane 11, a symbol group including B.12.35 and A.12.36 on lane 12, a symbol group including B.13.1 and A.13.1 on lane 13, a symbol group including B.14.35 and A.1436 on lane 14, and a symbol group including B.15.1 and A.15.1 on lane 15 are symbol groups, at a same location, in the symbol groups output through lane 8 to lane 15. On muxed lane 1, symbols that are included in eight symbol groups at other same locations and that are sequentially output after the symbol A. 15.0 may be represented as: B.8.35->A.8.36->B.9.1->A.9.1->B.10.35->A.10.36->B.11.1->A.11.1->B.12.35->A.12.36->B.13.1->A.13.1->B.14.35->A.14.36->B.15.1->A.15.1. Any eight consecutive symbol groups in symbol groups output through muxed lane 1 come from eight different lanes.

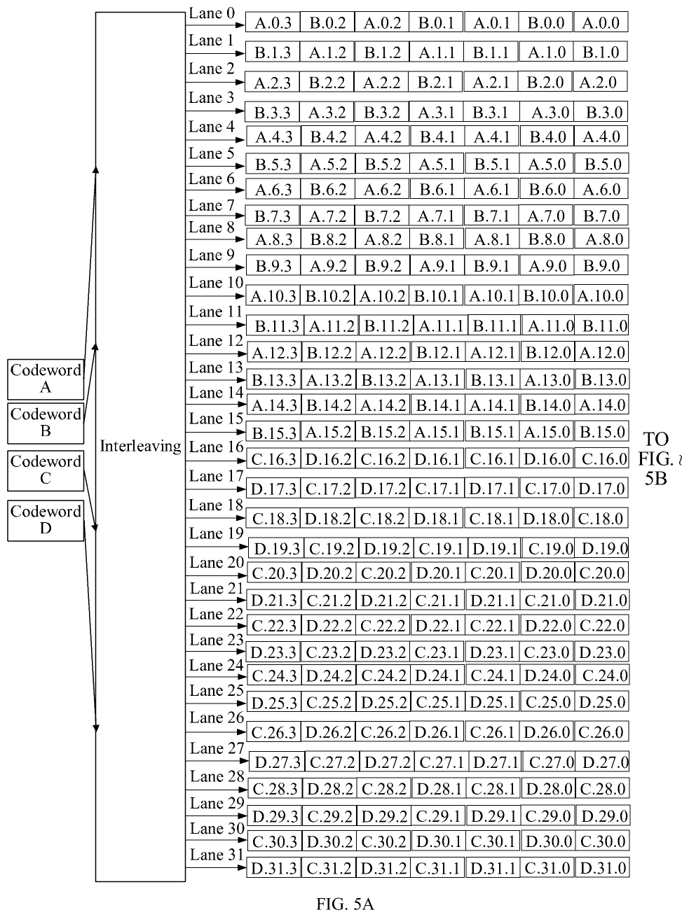

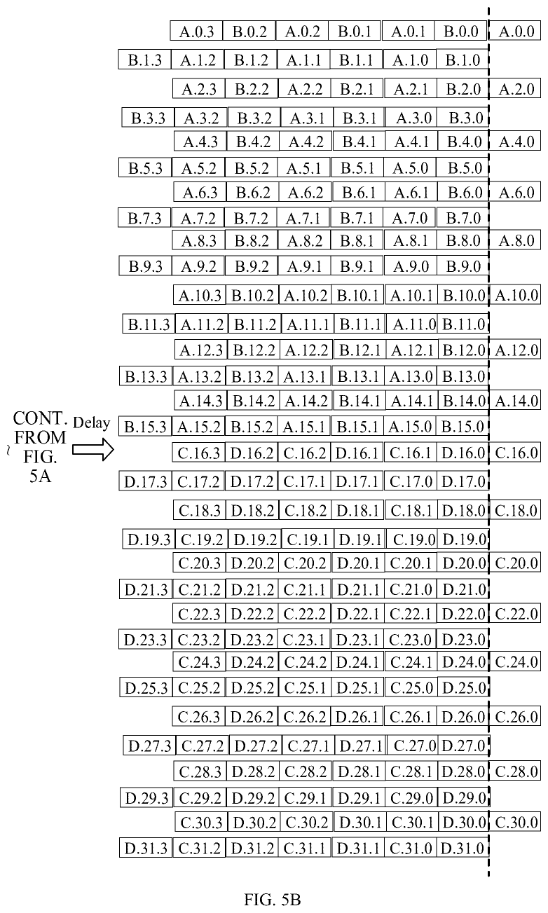

FIG. 5A, FIG. 5B, FIG. 5C, and FIG. 5D are embodiments in which there are two codeword groups, each codeword group includes two different codewords, a quantity of lanes for an input data stream is 32, and a quantity of lanes for an output data stream is 4. For a plurality of codeword groups, another scenario in which a ratio of a quantity of lanes for an input data stream to a quantity of lanes for an output data stream is 8:1, refer to a method in this embodiment. Examples are not described herein one by one.

FIG. 5A and FIG. 5B are a diagram of interleaving and shifting a plurality of codewords included in two codeword groups. In this embodiment, a first codeword group includes codeword A and codeword B, and a second codeword group includes codeword C and codeword D. After codeword A and codeword B that are included in the first codeword group are interleaved, a plurality of symbols are output through lane 0 to lane 15. After codeword C and codeword D that are included in the second codeword group are interleaved, a plurality of symbols are output through lane 16 to lane 31. For example, the first codeword group includes codeword A and codeword B. An order of symbols output through each lane with an even sequence number after codeword A and codeword B are interleaved is an order of ABABAB, and an order of symbols output through a lane with an odd sequence number after codeword A and codeword B are interleaved is an order of BABABA. For meanings of an identifier in each block, meanings of “adjacent”, and meanings of “consecutive” in FIG. 5A and FIG. 5B, refer to corresponding content in FIG. 3A. For a specific manner in which the plurality of symbols are output through lane 0 to lane 15 after codeword A and codeword B are interleaved, refer to corresponding content in FIG. 4A. A quantity of symbols included in codeword A and codeword B in FIG. 5A and FIG. 5B is L₃*544, where L₃ is an integer greater than or equal to 1. After being interleaved, symbols included in each codeword in the first codeword group are output through 16 lanes: lane 0 to lane 15. A quantity of output symbols of each lane is L₃*68, where L₃*34 symbols come from codeword A, and L₃*34 symbols come from codeword B. A quantity of symbols included in codeword C and codeword D in FIG. 5A and FIG. 5B is L₄*544, where L₄ is an integer greater than 0. After being interleaved, symbols included in each codeword in the second codeword group are output through 16 lanes: lane 16 to lane 31. A quantity of output symbols of each lane is L₄*68, where L₄*34 symbols come from codeword C, and L₄*34 symbols come from codeword D. The interleaving shown in FIG. 5A and FIG. 5B belongs to multi-to-multi interleaving. For details, refer to corresponding content in FIG. 3A. Codeword C and codeword D that are included in the second codeword group are used as an example. An order of symbols output through each lane with an even sequence number after codeword C and codeword D are interleaved is an order of CDCDCD, and an order of symbols output through each lane with an odd sequence number after codeword C and codeword D are interleaved is an order of DCDCDC. In this embodiment, some symbols obtained by interleaving the plurality of codewords included in the second codeword group are used as an example for description, and a quantity of symbols greater than that shown in the figure is not described by using an example. For example, any two lanes with even sequence numbers, for example, lane 16 and lane 28, are selected from lane 16 to lane 31. Symbols included in lane 16 and lane 28 come from codeword C and codeword D that are included in the codeword group. Symbols output through lane 16 after codeword C and codeword D are interleaved may be represented as: C.16.0->D.16.0->C.16.1->D.16.1->C.16.2->D.16.2->C.16.3-> . . . D.16.33->C.16.33. Symbols output through lane 28 after codeword C and codeword D are interleaved may be represented as: C.28.0->D.28.0->C.28.1->D.28.1->C.28.2->D.28.2->C.28.3-> . . . C.28.33->D.28.33. For example, any two lanes with odd sequence numbers are selected. Symbols included in lane 19 and lane 27 come from codeword C and codeword D that are included in the codeword group. Symbols output through lane 19 after codeword C and codeword D are interleaved may be represented as: D.19.0->C.19.0->D.19.1->C.19.1->D.19.2->C.19.2->D.19.3-> . . . >D.19.33->C.19.33. Symbols output through lane 27 after codeword C and codeword D are interleaved may be represented as: D.27.0->C.27.0->D.27.1->C.27.1->D.27.2->C.27.2->D.27.3-> . . . >D.27.33->C.27.33. For symbols output from any codeword group through 16 lanes, an order of symbols output through a lane with an odd sequence number is different from an order of symbols output through a lane with an even sequence number.

A transmitting end may shift an interleaved stream. For example, symbols output through one or more of lane 0 to lane 31 is sent after a delay, where a depth of the delay is a length of an odd quantity of symbols. For example, a length of an RS symbol is 10 bits. In this case, sending of data output through each of lane 1, lane 3, lane 5, lane 7, lane 9, lane 11, lane 13, lane 15, lane 17, lane 19, lane 21, lane 23, lane 25, lane 27, lane 29, and lane 31 is delayed by 10 bits, so that boundaries of symbols that are included in codeword A, codeword B, codeword C, and codeword D and that are output through lane 0 to lane 31 are aligned, as boundaries marked by a dotted line shown in FIG. 5A and FIG. 5B. The data is sent with the delay of the odd quantity of symbols, orders of symbols output through any two lanes after symbols from a same codeword group are interleaved can be the same. For example, sending on a lane with an odd sequence number in lane 0 to lane 15 is delayed by one symbol. A boundary of a symbol identified by B.1.0 on lane 1 on which the sending is delayed is aligned with a boundary of a symbol identified by B.0.0 on lane 0, and a boundary of a symbol identified by A.1.0 on lane 1 on which the sending is delayed is aligned with a boundary of a symbol identified by A.0.1 on lane 0. A boundary of a symbol identified by B.3.0 on lane 3 on which the sending is delayed is aligned with a boundary of a symbol identified by B.6.0 on lane 6, and a boundary of a symbol identified by A.3.0 on lane 3 on which the sending is delayed is aligned with a boundary of a symbol identified by A.6.1 on lane 6. A boundary of a symbol identified by B.5.0 on lane 5 on which the sending is delayed is aligned with a boundary of a symbol identified by B.2.0 on lane 2, and a boundary of a symbol identified by A.5.0 on lane 5 on which the sending is delayed is aligned with a boundary of a symbol identified by A.2.1 on lane 2. A boundary of a symbol identified by B.7.0 on lane 7 on which the sending is delayed is aligned with a boundary of a symbol identified by B.12.0 on lane 12, and a boundary of a symbol identified by A.7.0 on lane 7 on which the sending is delayed is aligned with a boundary of a symbol identified by A.12.1 on lane 12. A boundary of a symbol identified by B.11.0 on lane 11 on which the sending is delayed is aligned with a boundary of a symbol identified by B.4.0 on lane 4, and a boundary of a symbol identified by A. 11.0 on lane 11 on which the sending is delayed is aligned with a boundary of a symbol identified by A.4.1 on lane 4. A boundary of a symbol identified by B.13.0 on lane 13 on which the sending is delayed is aligned with a boundary of a symbol identified by B.10.0 on lane 10, and a boundary of a symbol identified by A.13.0 on lane 13 on which the sending is delayed is aligned with a boundary of a symbol identified by A.10.1 on lane 10. A boundary of a symbol identified by B.15.0 on lane 15 on which the sending is delayed is aligned with a boundary of a symbol identified by B.8.0 on lane 8, and a boundary of a symbol identified by A. 15.0 on lane 15 on which the sending is delayed is aligned with a boundary of a symbol identified by A.8.1 on lane 8. A boundary of a symbol identified by B.9.0 on lane 9 on which the sending is delayed is aligned with a boundary of a symbol identified by B.14.0 on lane 14, and a boundary of a symbol identified by A.9.0 on lane 9 on which the sending is delayed is aligned with a boundary of a symbol identified by A.14.1 on lane 14. For example, sending on a lane with an odd sequence number in lane 16 to lane 31 is delayed by one symbol. A boundary of a symbol identified by D.17.0 on lane 17 on which the sending is delayed is aligned with a boundary of a symbol identified by D.16.0 on lane 16, and a boundary of a symbol identified by C.17.0 on lane 17 on which the sending is delayed is aligned with a boundary of a symbol identified by C.16.1 on lane 16. A boundary of a symbol identified by D.19.0 on lane 19 on which the sending is delayed is aligned with a boundary of a symbol identified by D.22.0 on lane 22, and a boundary of a symbol identified by C.19.0 on lane 19 on which the sending is delayed is aligned with a boundary of a symbol identified by C.22.1 on lane 22. A boundary of a symbol identified by D.21.0 on lane 21 on which the sending is delayed is aligned with a boundary of a symbol identified by D.18.0 on lane 18, and a boundary of a symbol identified by C.21.0 on lane 21 on which the sending is delayed is aligned with a boundary of a symbol identified by C.18.1 on lane 18. A boundary of a symbol identified by D.23.0 on lane 23 on which the sending is delayed is aligned with a boundary of a symbol identified by D.28.0 on lane 28, and a boundary of a symbol identified by C.23.0 on lane 23 on which the sending is delayed is aligned with a boundary of a symbol identified by C.28.1 on lane 28. A boundary of a symbol identified by D.27.0 on lane 27 on which the sending is delayed is aligned with a boundary of a symbol identified by D.20.0 on lane 20, and a boundary of a symbol identified by C.27.0 on lane 27 on which the sending is delayed is aligned with a boundary of a symbol identified by C.20.1 on lane 20. A boundary of a symbol identified by D.29.0 on lane 29 on which the sending is delayed is aligned with a boundary of a symbol identified by D.26.0 on lane 26, and a boundary of a symbol identified by C.29.0 on lane 29 on which the sending is delayed is aligned with a boundary of a symbol identified by C.26.1 on lane 26. A boundary of a symbol identified by D.31.0 on lane 31 on which the sending is delayed is aligned with a boundary of a symbol identified by D.24.0 on lane 24, and a boundary of a symbol identified by C.31.0 on lane 31 on which the sending is delayed is aligned with a boundary of a symbol identified by C.24.1 on lane 24. A boundary of a symbol identified by D.25.0 on lane 25 on which the sending is delayed is aligned with a boundary of a symbol identified by D.30.0 on lane 30, and a boundary of a symbol identified by C.25.0 on lane 25 on which the sending is delayed is aligned with a boundary of a symbol identified by C.30.1 on lane 30. An order of symbols output through any one of lane 16 to lane 31 after the shifting is an order of DCDCDC.

FIG. 5C and FIG. 5D are a diagram of multiplexing data streams obtained through the shifting in FIG. 5A and FIG. 5B to obtain four data streams. In FIG. 5C and FIG. 5D, data streams that are obtained through the shifting and that are output through lane 0 to lane 31 include symbols that come from the first codeword group and that are output through lane 0 to lane 15 and symbols that come from the second codeword group and that are output through lane 16 to lane 31. Four data streams obtained by performing multiplexing by the transmitting end are respectively output through muxed lane 0, muxed lane 1, muxed lane 2, and muxed lane 3. Multiplexing methods of the data streams that are obtained through multiplexing and that are output through muxed lane 0, muxed lane 1, muxed lane 2, and the muxed lane 3 are the same. A method for obtaining a data stream output through muxed lane 1 is used as an example below for description. The transmitting end performs round-robin on symbol groups output through four lanes of lane 0 to lane 15 and symbol groups output through four lanes of lane 16 to lane 31, to obtain a data stream output through any muxed lane. The data stream output through muxed lane 1 is used as an example. A round-robin method for two cycles includes: obtaining, in an order of lane 4->lane 20->lane 5->lane 21->lane 6->lane 22->lane 7->lane 23, symbol groups output through the foregoing eight lanes. A symbol group including B.4.0 and A.4.1 on lane 4, a symbol group including D.20.0 and C.20.1 on lane 20, a symbol group including B.5.0 and A.5.0 on lane 5, a symbol group including D.21.0 and C.21.0 on lane 21, a symbol group including B.6.0 and A.6.1 on lane 6, a symbol group including D.22.0 and C.22.1 on lane 22, a symbol group including B.7.0 and A.7.0 on lane 7, and a symbol group including D.23.0 and C.23.0 on lane 23 are symbol groups at same locations on the eight selected lanes. The foregoing eight symbol groups are first sequentially output through muxed lane 1 in the order of lane 4->lane 20->lane 5->lane 21->lane 6->lane 22->lane 7->lane 23 (an order of lanes to which eight symbol groups output through muxed lane 1 in a first cycle belong in FIG. 5C and FIG. 5D). For example, the 16 symbols that come from the eight lanes and that are sequentially output through muxed lane 1 may be represented as: B.4.0->A.4.1->D.20.0->C.20.1->B.5.0->A.5.0->D.21.0->C.21.0->B.6.0->A.6.1->D.22.0->C.22.1->B.7.0->A.7.0->D.23.0->C.23.0. A symbol group including B.4.1 and A.4.2 on lane 4, a symbol group including D.20.1 and C.20.2 on lane 20, a symbol group including B.5.1 and A.5.1 on lane 5, a symbol group including D.21.1 and C.21.1 on lane 21, a symbol group including B.6.1 and A.6.2 on lane 6, a symbol group including D.22.1 and C.22.2 on lane 22, a symbol group including B.7.1 and A.7.1 on lane 7, and a symbol group including D.23.1 and C.23.1 on lane 23 are symbol groups, at other same locations, on the eight selected lanes. On muxed lane 1, the 16 symbols that are included in the eight symbol groups at the another same locations, that are obtained in a second cycle, and that are sequentially output after the symbol C.23.0 may be represented as: B.4.1->A.4.2->D.20.1->C.20.2->B.5.1->A.5.1->D.21.1->C.21.1->B.6.1->A.6.2->D.22.1->C.22.2->B.7.1->A.7.1->D.23.1->C.23.1. Any eight consecutive symbol groups in symbol groups output through muxed lane 1 come from eight different lanes: lane 4, lane 20, lane 5, lane 21, lane 6, lane 22, lane 7, and lane 23. For a multiplexing manner of symbols output through another muxed lane, refer to the multiplexing manner of the symbols output through muxed lane 1. Details are not described herein again. Due to the shifting, when symbols are output from data streams from a same codeword group, the symbols are sorted in a same order. Symbols that come from the first codeword group and that are output through any four lanes and symbols that come from the second codeword group and that are output through any lane are multiplexed based on the symbol group, to obtain symbols output through any muxed lane. In this way, a spacing between symbols that come from any codeword and that are in the symbols output through the muxed lane is 3 symbols. For example, an order of the symbols output through any muxed lane is an order of BADCBADC.

In another possible implementation, sending on lanes with even sequence numbers in lane 0 to lane 15 is delayed, and an order of symbols output through any one of lane 0 to lane 15 after the shifting is an order of ABABAB, and an order of symbols output through any one of lane 16 to lane 31 after the shifting is an order of CDCDCD. A rule of delaying sending on the lanes with the even sequence numbers is similar to a rule of delaying sending on the lanes with the odd sequence numbers. For details, refer to related content in FIG. 5A and FIG. 5B. After the sending on the lanes with the even sequence numbers is delayed, an order of symbols output through any muxed lane is an order of ABCDABCD. For a specific multiplexing method, refer to related content in FIG. 5C and FIG. 5D.

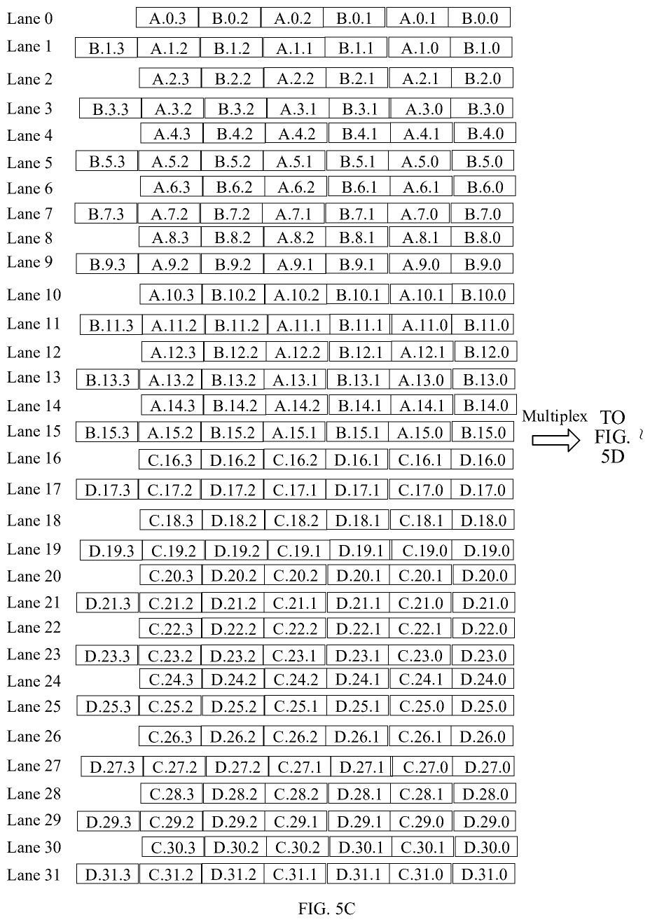

FIG. 6 is an embodiment in which there is one codeword group, the codeword group includes four different codewords, a quantity of lanes for input data streams is 16, and a quantity of lanes for output data streams is 8. For a codeword group including four codewords, another scenario in which a ratio of a quantity of lanes for input data streams to a quantity of lanes for an output data stream is 2:1, refer to a method in this embodiment. Examples are not described herein one by one. For meanings of “adjacent”, “consecutive”, the “symbol group”, the “symbol”, and the “codeword group” in FIG. 6, refer to corresponding content in FIG. 3A. A symbol group in FIG. 6 includes four symbols, and the four symbols come from different codewords. In this embodiment, a symbol group including four symbols may also be referred to as a symbol quartet, or four symbols from different codewords are referred to as a symbol quartet. Multiplexing of a symbol group including four symbols may also be referred to as RS symbol quartet multiplexing. In FIG. 6, data streams obtained by interleaving codeword A, codeword B, codeword C, and codeword D are output through lane 0 to lane 15. An order of symbols output through lane 0 to lane 15 is an order of ABCDABCD. Any symbol group includes four symbols, and the four symbols come from different codewords. An order of codewords from which the symbols in any symbol group come may be expressed as ABCD. A transmitting end multiplexes, based on the symbol group, the interleaved symbols that are output through lane 0 to lane 15, to obtain data streams output through muxed lane 0 to muxed lane 7, in other words, a data stream obtained by multiplexing on any two of lane 0 to lane 15 is output through one muxed lane. In FIG. 6, an example in which a symbol output through a lane with an odd sequence number and a symbol output through a lane with an even sequence number are multiplexed to obtain a muxed lane is used. In an order ABCDABCD of symbols on any lane, any two lanes may be selected, for example, a symbol output through a lane with an odd sequence number and a symbol output through another lane with an odd sequence number, or a symbol output through a lane with an even sequence number and a symbol output through another lane with an even sequence number. The following uses an example in which symbols output through muxed lane 4 are obtained by multiplexing, based on a symbol group, symbols output through lane 8 and symbols output through lane 9 for description. A symbol group including A.8.0, B.8.0, C.8.0, and D.8.0 on lane 8 and a symbol group including A.9.0, B.9.0, C.9.0, and D.9.0 on lane 9 are at same locations, the transmitting end obtains the two symbol groups in a first cycle, and outputs the symbol groups to muxed lane 4 in an order of lane 8->lane 9, which may be specifically represented as: A.8.0->B.8.0->C.8.0->D.8.0->A.9.0->B.9.0->C.9.0->D.9.0. A symbol group including A.8.1, B.8.1, C.8.1, and D.8.1 on lane 8 and a symbol group including A.9.1, B.9.1, C.9.1, and D.9.1 on lane 9 are at other same locations, the transmitting end obtains the two symbol groups in a second cycle, and after outputting the symbol D.9.0 in the first cycle, outputs symbols to muxed lane 4 in an order of lane 8->lane 9, which may be specifically represented as: A.8.1->B.8.1->C.8.1->D.8.1->A.9.1->B.9.1->C.9.1->D.9.1. In the foregoing round-robin order, round-robin is performed on symbol groups at same locations on two lanes in each cycle, and the symbol groups are sequentially transmitted through a muxed lane; and round-robin is sequentially performed in a plurality of consecutive cycles, until all symbols included in the codeword group are output. Two consecutive symbol groups output through any muxed lane respectively come from different lanes. An order of codewords to which symbols output through any muxed lane belong is an order of ABCDABCD.

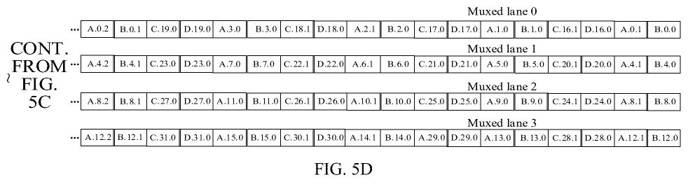

FIG. 7 is a schematic flowchart of another data processing method according to an embodiment. The method shown in FIG. 7 is performed by a receiving end. The receiving end may be a module or a chip that acts as a receiving role. The module or the chip may be disposed in a host or an optical module. In this embodiment, data processing performed by the receiving end may be a reverse process of the data processing performed by the transmitting end in FIG. 2 and related embodiments.

701: The receiving end obtains an input data stream.

For example, the input data stream obtained by the receiving end is an output data stream obtained by a transmitting end. The input data stream obtained by the receiving end may be a data stream output by the transmitting end through b lanes, where b is an integer greater than or equal to 1. The receiving end may also use the data stream transmitted through the b lanes as the input data stream. For example, the input data stream obtained by the receiving end may be the data stream transmitted through the muxed lane in FIG. 3B, the data streams transmitted through muxed lane 0 and muxed lane 1 in FIG. 4B, the data streams transmitted through muxed lane 0 to muxed lane 3 in FIG. 5C and FIG. 5D, or the data streams transmitted through muxed lane 0 to muxed lane 7 in FIG. 6. For specific meanings of the symbol, the symbol group, the codeword, and the codeword group in the input data stream obtained by the receiving end, refer to corresponding content in related embodiments in FIG. 2 to FIG. 6. Details are not described herein again.

702: The receiving end demultiplexes the input data stream based on a symbol group, to obtain output data streams.

For example, the symbol group based on which the receiving end performs the demultiplexing has a same meaning as the symbol group based on which the transmitting end performs the multiplexing. For details, refer to corresponding content in related embodiments in FIG. 2 to FIG. 6. Details are not described herein again. The output data streams obtained by the receiving end may be output through a lanes, where a is an integer greater than or equal to 2, and a>b. The symbol group includes a plurality of symbols, and data included in the plurality of symbols comes from different codewords of the transmitting end. The output data streams obtained by the receiving end are used to obtain codewords that are the same as those of the transmitting end. Specifically, the receiving end de-interleaves the output data streams to obtain the codewords that are the same as those of the transmitting end, or the receiving end performs shifting and de-interleaving on the output data streams to obtain the codewords that are the same as those of the transmitting end. The foregoing de-interleaving process is a reverse process of an interleaving process of the transmitting end. Both the de-interleaving and the interleaving of the transmitting end use a symbol as a granularity. Details are not described herein again. After obtaining the codewords that are the same as those of the transmitting end, the receiving end may further decode the codewords. A specific decoding code type is the same as an encoding code type used by the transmitting end. Details are not described herein again.

For example, for 200GBASE-R and 400GBASE-R, symbols included in a data stream that is of the input data stream and that is transmitted through a same lane come from different codewords in a same codeword group, and two adjacent symbols come from different codewords; and symbols from different codewords in symbol groups included in the data stream that is of the input data stream and that is transmitted through the same lane are sorted in a same order, and a quantity of symbols included in the symbol group is the same as a quantity of codewords. For example, the symbol group includes two symbols. For 800GBASE-R, symbols included in a data streams that is of the input data stream and that is transmitted through a same lane come from different codewords included in two codeword groups, and two adjacent symbols come from different codewords; and two adjacent symbol groups included in the data stream that is of the input data stream and that is transmitted through the same lane come from different codeword groups. For symbol groups from a same codeword group, symbols from different codewords in the same codeword group in the symbol group are sorted in a same order. For example, the symbol group includes two symbols. For example, for 1.6TGBASE-R, symbols included in a data stream that is of the input data stream and that is transmitted through a same lane come from different codewords in a same codeword group, and two adjacent symbols come from different codewords. Symbols from different codewords in symbol groups included in the data stream that is of the input data stream and that is transmitted through the same lane are sorted in a same order, and a quantity of symbols included in the symbol group is the same as a quantity of codewords. For example, the symbol group includes four symbols. For meanings of “consecutive” and “adjacent” in this embodiment, refer to corresponding content in the embodiment corresponding to FIG. 2.

For example, the receiving end obtains one of the b lanes for the input data stream. The receiving end sequentially obtains a₁ symbol groups from a data stream output through the lane, and separately distributes the a₁ symbol groups to ai lanes of the a lanes used to obtain the output data streams, where a₁ is an integer less than or equal to a. After completing a previous round of distribution, the receiving end obtains a₂ symbol groups after the a₁ symbol groups from the data stream output through the lane, and separately distributes the a₂ symbol groups to the a₁ lanes, where a value of a₂ is the same as that of a₁. For all of the b lanes, a distribution principle of each lane is the same as the foregoing distribution principle of one lane. Details are not described herein again.

Optionally, the receiving end may perform a shifting operation on a data streams obtained through the demultiplexing, to restore a data streams that are the same as a data streams obtained through interleaving by the transmitting end. For a specific manner of the shifting operation performed by the receiving end, refer to the manner of the shifting operation performed by the transmitting end, that is, delayed sending. A difference between the shifting operation performed by the receiving end and the shifting operation performed by the transmitting end lies in that a lane on which data shifted by the receiving end is located is different from a lane on which data shifted by the transmitting end is located. For example, if the transmitting end delays, by N bits, sending of data transmitted through a lane with an odd sequence number, where N is an integer greater than or equal to 1, the receiving end delays, by N bits, sending of data transmitted through a lane with an even sequence number. If the transmitting end delays, by N bits, sending of data transmitted through a lane with an even sequence number, the receiving end delays, by N bits, sending of data transmitted through a lane with an odd sequence number.

In the method provided in this embodiment, the transmitting end performs multiplexing based on the symbol group including the symbols. In this way, even if a burst error of a plurality of consecutive bits occur in the obtained output data stream in a transmission process, after the receiving end performs demultiplexing based on the symbol group, the burst error of the plurality of consecutive bits affect only a small quantity of symbols, in other words, a quantity of symbols that are of the data stream multiplexed based on the symbol group and that are affected by the burst error of the plurality of consecutive bits is far less than a quantity of symbols that are of a data stream multiplexed based on a bit and that are affected by the burst error of the plurality of consecutive bits, so that error correction performance and system reliability are improved.

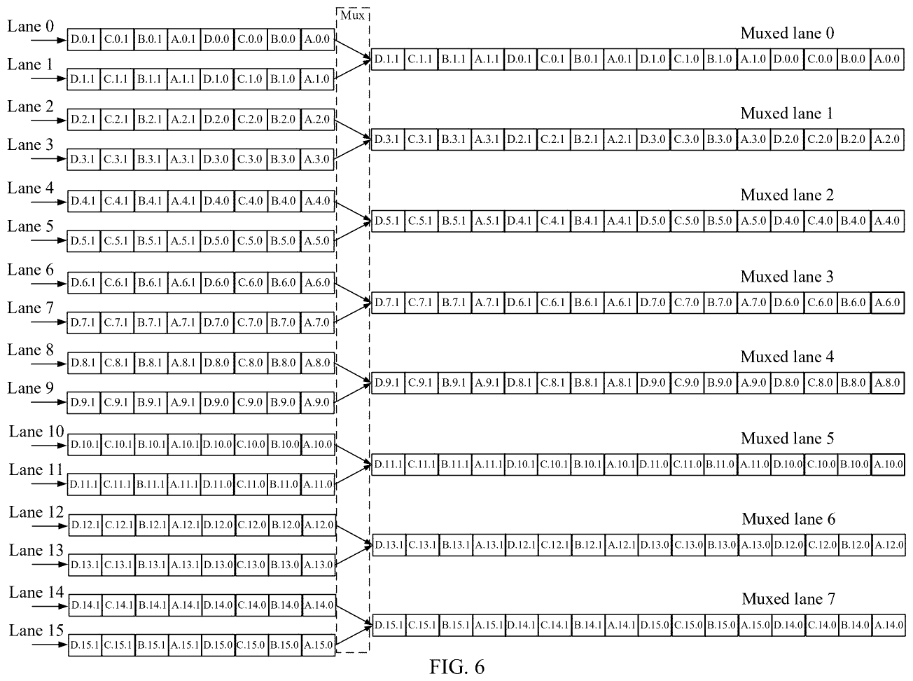

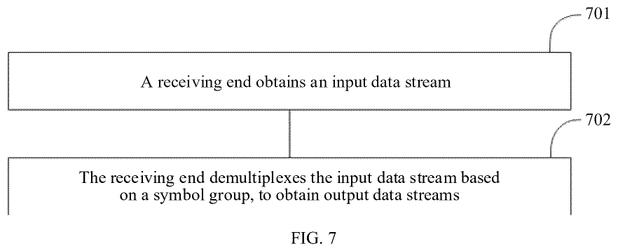

FIG. 8A and FIG. 8B are embodiments in which a codeword group includes two different codewords, symbols of one codeword group are demultiplexed, a quantity of lanes for an input data stream is 1, and a quantity of lanes for an output data stream is 8. For a codeword group including two different codewords, a method in this embodiment may also be used in another scenario in which a ratio of a quantity of lanes for an input data stream to a quantity of lanes for an output data stream is 1:8. Examples are not described herein one by one. A receiving end in FIG. 8A and FIG. 8B may be a host or chip based on 200GBASE-R.

The input data stream in FIG. 8A is the output data stream in FIG. 3B. For meanings of an identifier, a symbol, a symbol group, and a codeword group in blocks in FIG. 8A, refer to corresponding content in FIG. 3B and FIG. 3A. Meanings of “consecutive” and “adjacent” in this embodiment are the same as corresponding content in the embodiment corresponding to FIG. 2. Details are not described herein again. Symbols in FIG. 8A come from a codeword group including codeword A and codeword B. The receiving end obtains, in a unit of a symbol group including two symbols, eight consecutive symbol groups from a muxed lane, and sequentially outputs the symbol groups to lane 0 to lane 7. For example, a symbol group including B.0.68 and A.0.69 is output through lane 0, a symbol group including B.1.0 and A.1.0 is output through lane 1, a symbol group including B.2.68 and A.2.69 is output through lane 2, a symbol group including B.3.0 and A.3.0 is output through lane 3, a symbol group including B.4.68 and A.4.69 is output through lane 4, a symbol group including B.5.0 and A.5.0 is output through lane 5, a symbol group including B.6.68 and A.6.69 is output through lane 6, and a symbol group including B.7.0 and A.7.0 is output through lane 7. After demultiplexing of the foregoing eight symbol groups is completed, the receiving end continues to obtain, from the muxed lane, eight consecutive symbol groups after the symbol group including B.7.0 and A.7.0, and sequentially outputs the symbol groups to lane 0 to lane 7. Based on the foregoing manner in which every eight consecutive symbol groups are sequentially output to lane 0 to lane 7, all symbols that come from codeword A and codeword B and that are output through the muxed lane are demultiplexed to lane 0 to lane 7.

The receiving end delays, by 137 symbols, sending of a data stream output through a lane with an even sequence number in FIG. 8A, as shown in FIG. 8B. After sending on lane 0, lane 2, lane 4, and lane 6 of lane 0 to lane 7 is delayed by 137 symbols, B.0.68 on lane 0, A.1.68 on lane 1, B.2.68 on lane 2, A.3.68 on lane 3, B.4.68 on lane 4, A.5.68 on lane 5, B.6.68 on lane 6, and A.7.68 on lane 7 are symbols at same locations on lane 0 to lane 7, in other words, symbol boundaries of the foregoing eight symbols are aligned. A symbol group including B.0.68 and A.0.69 on lane 0, a symbol group including B.1.69 and A. 1.68 on lane 1, a symbol group including B.2.68 and A.2.69 on lane 2, a symbol group including B.3.69 and A.3.68 on lane 3, a symbol group including B.4.68 and A.4.69 on lane 4, a symbol group including B.5.69 and A.5.68 on lane 5, a symbol group including B.6.68 and A.6.69 on lane 6, and a symbol group including B.7.69 and A.7.68 on lane 7 are symbol groups at same locations on lane 0 to lane 7. Symbols on a right side of a dashed line in FIG. 8B represents symbols that come from codeword A and codeword B and that are received by the receiving end. To be specific, after L₁*544 symbols starting from A.0.0, B.1.0, A.2.0, B.3.0, A.4.0, B.5.0, A.6.0, and B.7.0 are all obtained by the receiving end, where L₁ is an integer greater than or equal to 1, the receiving end may perform de-interleaving and decoding processing in an order of symbols in solid-line boxes and symbols in the symbols on a right side of a dashed line in FIG. 8B. After the delayed sending, symbols at same locations on any two adjacent lanes come from different codewords, and two consecutive symbols on any lane come from different codewords. Through the foregoing delayed sending, the receiving end restores a symbol order that is the same as that obtained by the transmitting end, so that a decoder can complete a decoding operation subsequently.

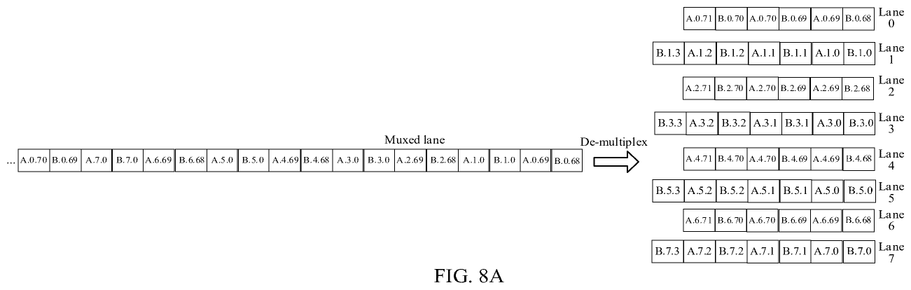

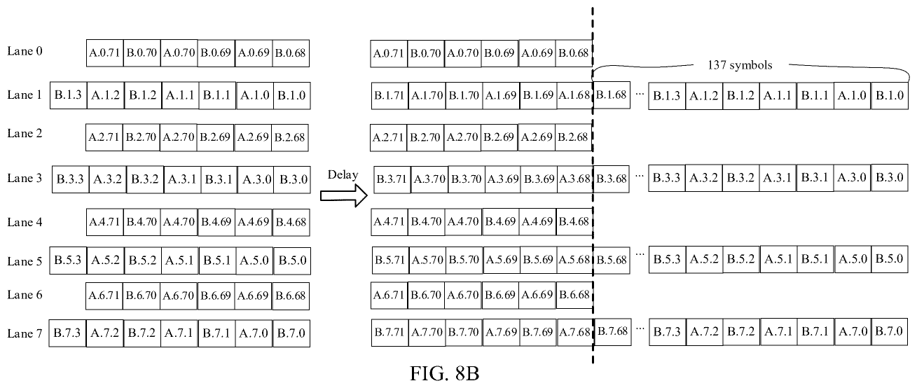

FIG. 9A, FIG. 9B, and FIG. 9C are embodiments in which a codeword group includes two different codewords, symbols of one codeword group are demultiplexed, a quantity of lanes for an input data stream is 2, and a quantity of lanes for an output data stream is 16. For a codeword group including two different codewords, a method in this embodiment may also be used in another scenario in which a ratio of a quantity of lanes for an input data stream to a quantity of lanes for an output data stream is 2:16. Examples are not described herein one by one. A receiving end in FIG. 9A, FIG. 9B, and FIG. 9C may be a host or chip based on 400GBASE-R.

The input data stream in FIG. 9A is the output data stream in FIG. 4B. For meanings of an identifier, a symbol, a symbol group, and a codeword group in blocks in FIG. 9A, refer to corresponding content in FIG. 4B and FIG. 4A. Meanings of “consecutive” and “adjacent” in this embodiment are the same as corresponding content in the embodiment corresponding to FIG. 2. Details are not described herein again. Symbols in FIG. 9A come from a codeword group including codeword A and codeword B. The receiving end obtains eight consecutive symbol groups separately from muxed lane 0 and muxed lane 1 in a unit of a symbol group including two symbols, and sequentially outputs the symbol groups to lane 0 to lane 15. Specifically, the receiving end obtains eight consecutive symbol groups in a unit of a symbol group including two symbols from muxed lane 0, and sequentially outputs the symbol groups to lane 0 to lane 7; and the receiving end obtains eight consecutive symbol groups from muxed lane 1 in a unit of a symbol group including two symbols, and sequentially outputs the symbol groups to lane 8 to lane 15. The 16 symbol groups are demultiplexed to same locations of corresponding lanes of lane 0 to lane 15. For example, a symbol group including B.0.34 and A.0.35 is output through lane 0, a symbol group including B.1.0 and A. 1.0 is output through lane 1, a symbol group including B.2.34 and A.2.35 is output through lane 2, a symbol group including B.3.0 and A.3.0 is output through lane 3, a symbol group including B.4.34 and A.4.35 is output through lane 4, a symbol group including B.5.0 and A.5.0 is output through lane 5, a symbol group including B.6.34 and A.6.35 is output through lane 6, and a symbol group including B.7.0 and A.7.0 is output through lane 7. After demultiplexing of the eight consecutive symbol groups from muxed lane 0 is completed, the receiving end continues to obtain eight consecutive symbol groups from muxed lane 1 and demultiplexes the eight consecutive symbol groups. A symbol group including B.8.34 and A.8.35 is output through lane 8, a symbol group including B.9.0 and A.9.0 is output through lane 9, a symbol group including B.10.34 and A.10.35 is output through lane 10, a symbol group including B.11.0 and A.11.0 is output through lane 11, a symbol group including B.12.34 and A. 12.35 is output through lane 12, a symbol group including B.13.0 and A. 13.0 is output through lane 13, a symbol group including B.14.34 and A.14.35 is output through lane 14, and a symbol group including B.15.0 and A.15.0 is output through lane 15. After the receiving end demultiplexes the 16 symbol groups, a symbol group including B.0.34 and A.0.35, a symbol group including B.1.0 and A.1.0, a symbol group including B.2.34 and A.2.35, a symbol group including B.3.0 and A.3.0, a symbol group including B.4.34 and A.4.35, a symbol group including B.5.0 and A.5.0, a symbol group including B.6.34 and A.6.35, and a symbol group including B.7.0 and A.7.0, a symbol group including B.8.34 and A.8.35, a symbol group including B.9.0 and A.9.0, a symbol group including B.10.34 and A.10.35, a symbol group including B.11.0 and A.11.0, a symbol group including B.12.34 and A.12.35, a symbol group including B.13.0 and A.13.0, a symbol group including B.14.34 and A.14.35, and a symbol group including B.15.0 and A.15.0 are symbol groups at same locations on corresponding lanes of lane 0 to lane 15. The receiving end continues to obtain eight consecutive symbol groups after A.7.0 on muxed lane 0 and eight consecutive symbol groups after A.15.0 on muxed lane 1, and performs demultiplexing according to the foregoing method, until all symbols that come from codeword A and codeword B and that are output through muxed lane 0 and muxed lane 1 are demultiplexed to lane 0 to lane 15.

The receiving end delays, by 69 symbols, sending of a data stream output through a lane with an even sequence number in FIG. 9A, as shown in FIG. 9B and FIG. 9C. After sending on lane 0, lane 2, lane 4, lane 6, lane 8, lane 10, lane 12, and lane 14 of lane 0 to lane 15 are delayed by 69 symbols, B.0.34 on lane 0, A. 1.34 on lane 1, B.2.34 on lane 2, A.3.34 on lane 3, B.4.34 on lane 4, A.5.34 on lane 5, B.6.34 on lane 6, A.7.34 on lane 7, B.8.34 on lane 8, A.9.34 on lane 9, B.10.34 on lane 10, A.11.34 on lane 11, B.12.34 on lane 12, A.13.34 on lane 13, B.14.34 on lane 14, and A.15.34 on lane 15 are symbols at same locations on lane 0 to lane 15, in other words, symbol boundaries of the foregoing 16 symbols are aligned. A symbol group including B.0.34 and A.0.35 on lane 0, a symbol group including B.1.35 and A. 1.34 on lane 1, a symbol group including B.2.34 and A.2.35 on lane 2, a symbol group including B.3.35 and A.3.34 on lane 3, a symbol group including B.4.34 and A.4.35 on lane 4, a symbol group including B.5.35 and A.5.34 on lane 5, a symbol group including B.6.34 and A.6.35 on lane 6, a symbol group including B.7.35 and A.7.34 on lane 7, a symbol group including B.8.34 and A.8.35 on lane 8, a symbol group including B.9.35 and A.9.34 on lane 9, a symbol group including B.10.34 and A. 10.35 on lane 10, a symbol group including B.11.35 and A.11.34 on lane 11, a symbol group including B.12.34 and A.12.35 on lane 12, a symbol group including B.13.35 and A.13.34 on lane 13, a symbol group including B.14.34 and A.14.35 on lane 14, and a symbol group including B.15.35 and A.15.34 on lane 15 are symbol groups at same locations on lane 0 to lane 15. Symbols on a right side of a dashed line in FIG. 9B and FIG. 9C represents symbols that come from codeword A and codeword B and that are received by the receiving end. To be specific, after L₂*544 symbols starting from A.0.0, B.1.0, A.2.0, B.3.0, A.4.0, B.5.0, A.6.0, B.7.0, A.8.0, B.9.0, A.10.0, B.11.0, A.12.0, B.13.0, A. 14.0, and B.15.0 are all obtained by the receiving end, where L₂ is an integer greater than or equal to 1, the receiving end may perform de-interleaving and decoding processing in an order of symbols in solid-line boxes and symbols in the symbols on a right side of a dashed line in FIG. 9B and FIG. 9C. After the delayed sending, symbols at same locations on any two adjacent lanes come from different codewords, and two consecutive symbols on any lane come from different codewords. Through the foregoing delayed sending, the receiving end restores a symbol order that is the same as that obtained by the transmitting end, so that a decoder can complete a decoding operation subsequently.

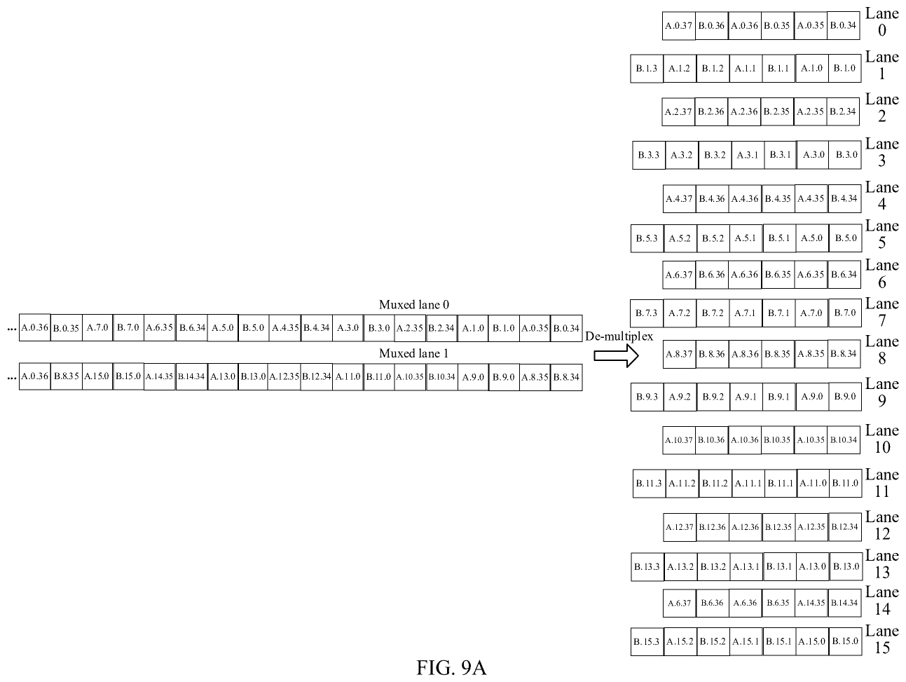

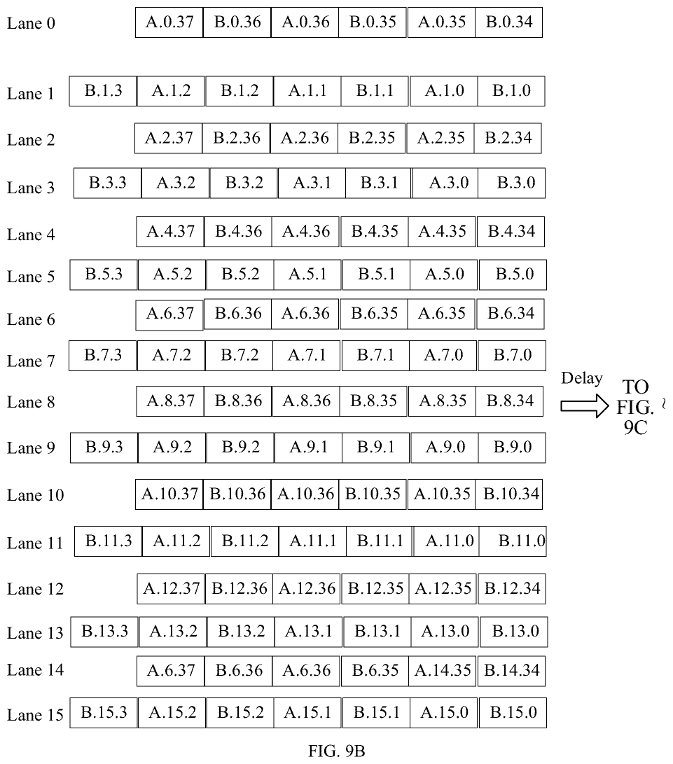

FIG. 10A, FIG. 10B, FIG. 10C, and FIG. 10D are embodiments in which a codeword group includes two different codewords, symbols of two codeword groups are demultiplexed, a quantity of lanes for an input data stream is 4, and a quantity of lanes for an output data stream is 32. For a plurality of codeword groups, a method in this embodiment may also be used in another scenario in which a ratio of a quantity of lanes for an input data stream to a quantity of lanes for an output data stream is 4:32. Examples are not described herein one by one. A receiving end in FIG. 10A, FIG. 10B, FIG. 10C, and FIG. 10D may be a host or chip based on 800GBASE-R.

The input data stream in FIG. 10A and FIG. 10B is the output data stream in FIG. 5C and FIG. 5D. For meanings of an identifier, a symbol, a symbol group, and a codeword group in blocks in FIG. 10A and FIG. 10B, refer to corresponding content in FIG. 5C, FIG. 5D, FIG. 5A, and FIG. 5B. Meanings of “consecutive” and “adjacent” in this embodiment are the same as corresponding content in the embodiment corresponding to FIG. 2. Details are not described herein again. Symbols in FIG. 10A come from two codeword groups, a first codeword group in the two codeword groups includes codeword A and codeword B, and a second codeword group in the two codeword groups includes codeword C and codeword D. The receiving end obtains, in a unit of a symbol group including two symbols, eight consecutive symbol groups through each lane of muxed lane 0 to muxed lane 3, and sequentially outputs the symbol groups to lane 0 to lane 31. Specifically, the receiving end obtains, in a unit of a symbol group including two symbols, eight consecutive symbol groups through muxed lane 0, and sequentially outputs the symbol groups to four lanes of lane 0 to lane 15 and four lanes of lane 16 to lane 31; the receiving end obtains, in a unit of a symbol group including two symbols, eight consecutive symbol groups through muxed lane 1, and sequentially outputs the symbol groups to four lanes of lane 0 to lane 15 and four lanes of lane 16 to lane 31; the receiving end obtains, in a unit of a symbol group including two symbols, eight consecutive symbol groups through muxed lane 2, and sequentially outputs the symbol groups to four lanes of lane 0 to lane 15 and four lanes of lane 16 to lane 31; and the receiving end obtains, in a unit of a symbol group including two symbols, eight consecutive symbol groups through muxed lane 3, and sequentially outputs the symbol groups to four lanes of lane 0 to lane 15 and four lanes of lane 16 to lane 31. The 32 symbol groups are demultiplexed to same locations of corresponding lanes of lane 0 to lane 31, and any one of muxed lane 0 to muxed lane 3 is demultiplexed to eight completely different lanes. For example, a symbol group including B.0.0 and A.0.0 is output through lane 0, a symbol group including B.1.0 and A.1.0 is output through lane 1, a symbol group including B.2.0 and A.2.0 is output through lane 2, a symbol group including B.3.0 and A.3.0 is output through lane 3, a symbol group including B.4.0 and A.4.0 is output through lane 4, a symbol group including B.5.0 and A.5.0 is output through lane 5, a symbol group including B.6.0 and A.6.0 is output through lane 6, a symbol group including B.7.0 and A.7.0 is output through lane 7, a symbol group including B.8.0 and A.8.0 is output through lane 8, a symbol group including B.9.0 and A.9.0 is output through lane 9, a symbol group including B.10.0 and A. 10.0 is output through lane 10, a symbol group including B.11.0 and A. 11.0 is output through lane 11, a symbol group including B.12.0 and A. 12.0 is output through lane 12, a symbol group including B.13.0 and A. 13.0 is output through lane 13, a symbol group including B. 14.0 and A.14.0 is output through lane 14, and a symbol group including B.15.0 and A.15.0 is output through lane 15. The 16 symbol groups including the symbols from the first codeword group are located at a same location on each of lane 0 to lane 15, in other words, boundaries of the symbols included in the 16 symbol groups are aligned. A process of demultiplexing the symbols from the second codeword group is the same as the foregoing process of demultiplexing the symbols from the first codeword group. Details are not described herein again. The receiving end performs demultiplexing according to the foregoing method, until all symbols that come from the first codeword group and the second codeword group and that are output through muxed lane 0 to muxed lane 3 are demultiplexed to lane 0 to lane 31.

The receiving end delays, by one symbol, sending of a data stream output through a lane with an even sequence number in FIG. 10A and FIG. 10B, as shown in FIG. 10C and FIG. 10D. After sending on lane 0, lane 2, lane 4, lane 6, lane 8, lane 10, lane 12, lane 14, lane 16, lane 18, lane 20, lane 22, lane 24, lane 26, lane 28, and lane 30 of lane 0 to lane 31 is delayed by one symbol, B.0.0 on lane 0, A. 1.0 on lane 1, B.2.0 on lane 2, A.3.0 on lane 3, B.4.0 on lane 4, A.5.0 on lane 5, B.6.0 on lane 6, A.7.0 on lane 7, B.8.0 on lane 8, A.9.0 on lane 9, B. 10.0 on lane 10, A.11.0 on lane 11, B.12.0 on lane 12, A. 13.0 on lane 13, B.14.0 on lane 14, A.15.0 on lane 15, D.16.0 on lane 16, C.17.0 on lane 17, D.18.0 on lane 18, C.19.0 on lane 19, D.20.0 on lane 20, C.21.0 on lane 21, D.22.0 on lane 22, C.23.0 on lane 23, D.24.0 on lane 24, C.25.0 on lane 25, D.26.0 on lane 26, C.27.0 on lane C, C.28.0 on lane 28, C.29.0 on lane 29, D.30.0 on lane 30, and C.31.0 on lane 31 are symbols at same locations on lane 0 to lane 31, in other words, symbol boundaries of the 32 symbols are aligned. A symbol group including the 32 symbols is a symbol group at a same location on each of lane 0 to lane 31. Symbols on a right side of a dashed line in FIG. 10C and FIG. 10D represents symbols that come from codeword A, codeword B, codeword C, and codeword D and that are received by the receiving end. To be specific, after L₃*544 symbols starting from A.0.0, B.1.0, A.2.0, B.3.0, A.4.0, B.5.0, A.6.0, B.7.0, A.8.0, B.9.0, A.10.0, B.11.0, A.12.0, B.13.0, A.14.0, B.15.0, C.16.0, D.17.0, C.18.0, D.19.0, C.20.0, D.21.0, C.22.0, D.23.0, C.24.0, D.25.0, C.26.0, D.27.0, C.28.0, D.29.0, C.30.0, and D.31.0 are all obtained by the receiving end, where L₃ is an integer greater than or equal to 1, the receiving end may perform de-interleaving and decoding processing in an order of symbols in solid-line boxes and symbols in the symbols on a right side of a dashed line in FIG. 10C and FIG. 10D. After the delayed sending, symbols at same locations on any two adjacent lanes come from different codewords, and two consecutive symbols on any lane come from different codewords. Through the foregoing delayed sending, the receiving end restores a symbol order that is the same as that obtained by a transmitting end, so that a decoder can complete a decoding operation subsequently.

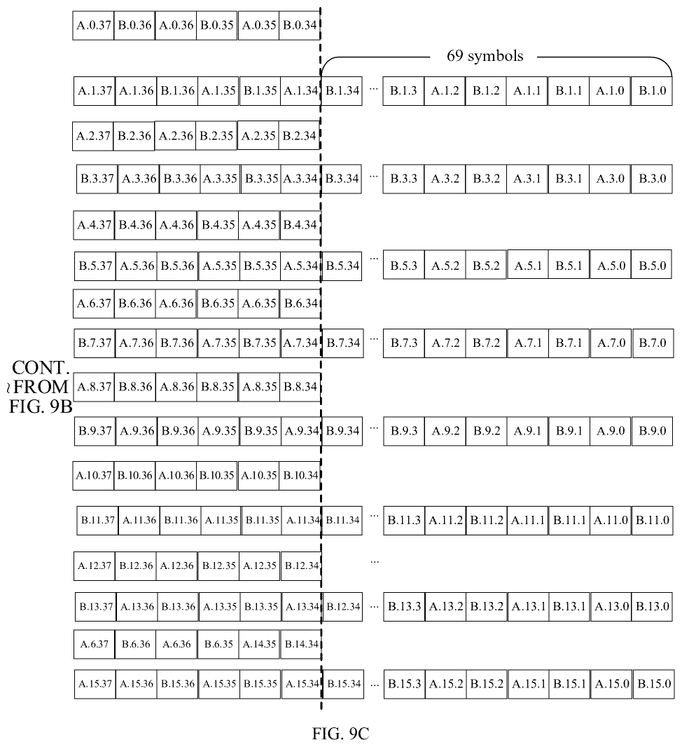

FIG. 11 is an embodiment in which a codeword group includes four different codewords, symbols of one codeword group are demultiplexed, a quantity of lanes for an input data stream is 8, and a quantity of lanes for an output data stream is 16. For a codeword group including four codewords, a method in this embodiment may also be used in another scenario in which a ratio of a quantity of lanes for an input data stream to a quantity of lanes for an output data stream is 8:16. Examples are not described herein one by one. A receiving end in FIG. 11 may be a host or chip based on 1.6TGBASE-R.

The input data stream in FIG. 11 is the output data stream in FIG. 6. For meanings of an identifier, a symbol, a symbol group, and a codeword group in blocks in FIG. 11, refer to corresponding content in FIG. 6. Meanings of “consecutive” and “adjacent” in this embodiment are the same as corresponding content in the embodiment corresponding to FIG. 2. Details are not described herein again. Symbols in FIG. 11 come from a codeword group including four codewords, and the four codewords include codeword A, codeword B, codeword C, and codeword D. The receiving end obtains, in a unit of a symbol group including four symbols, two consecutive symbol groups through each lane of muxed lane 0 to muxed lane 7, and sequentially outputs the symbol groups to lane 0 to lane 15. Specifically, the receiving end obtains, in a unit of a symbol group including four symbols, two consecutive symbol groups through muxed lane 0, and sequentially outputs the symbol groups to lane 0 and lane 1; the receiving end obtains, in a unit of a symbol group including four symbols, two consecutive symbol groups through muxed lane 1, and sequentially outputs the symbol groups to lane 2 and lane 3; the receiving end obtains, in a unit of a symbol group including four symbols, two consecutive symbol groups through muxed lane 2, and sequentially outputs the symbol groups to lane 4 and lane 5; and the receiving end obtains, in a unit of a symbol group including four symbols, two consecutive symbol groups through muxed lane 3, and sequentially outputs the symbol groups to lane 6 and lane 7. A method for demultiplexing muxed lane 4 to muxed lane 7 to lane 8 to lane 15 by the receiving end is the same as the foregoing method for demultiplexing muxed lane 0 to muxed lane 3 to lane 0 to lane 7. After the foregoing demultiplexing, orders of codewords from which symbols in any symbol group on lane 0 to lane 15 come are the same, and are all ABCD. The receiving end restores a symbol order that is the same as that obtained by a transmitting end, so that a decoder can complete a decoding operation subsequently.

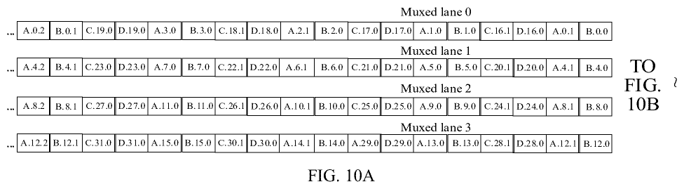

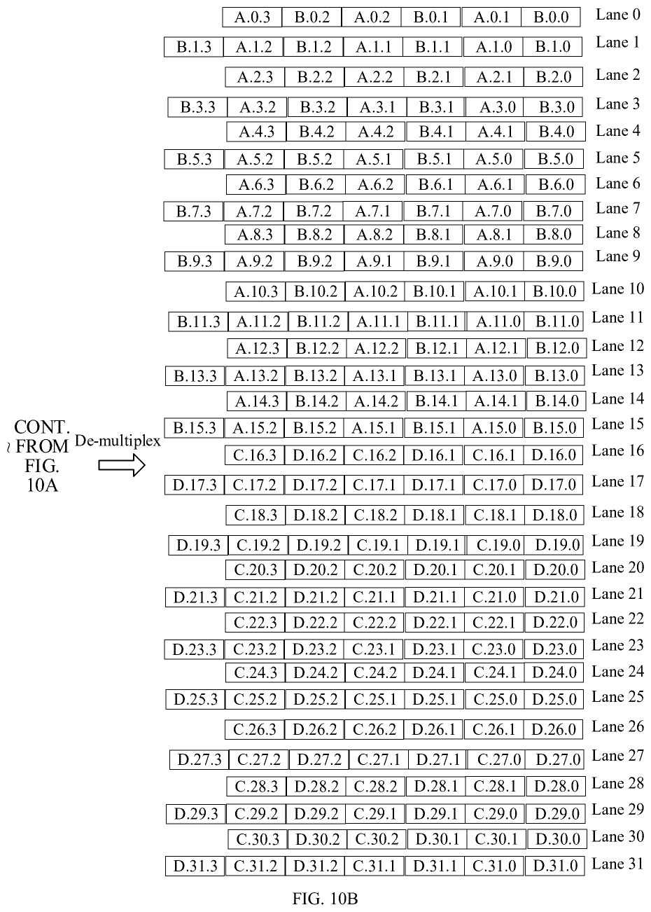

A hardware structure shown in FIG. 12A includes a reconciliation sublayer, a PCS, two PMA layers, an inner FEC layer, a physical medium dependent (PMD) layer, and a medium that are sequentially arranged. A medium independent interface (MII) is disposed between the RS and the PCS, and an attachment unit interface (AUI) is disposed between the two PMA layers. A medium dependent interface (MDI) is disposed between the PMD layer and the medium. The medium may be a coaxial cable, an optical fiber, a twisted-pair cable, or the like. The data processing method in the embodiments corresponding to FIG. 2 to FIG. 11 may be implemented by the PMA layer between the PCS and the AUI in FIG. 12A. In this case, data of 200 G/lane is transmitted through the AUI, the PMA layer between the AUI and the inner FEC may transparently transmit data transmitted through the AUI. Alternatively, the data processing method in the embodiments corresponding to FIG. 2 to FIG. 11 is implemented by the PMA layer between the AUI and the inner FEC layer in FIG. 12A. In this case, data of 100 G/lane is transmitted through the AUI, the PMA layer between the AUI and the inner FEC may perform bit-level multiplexing or transparently transmit data of the PCS. The RS is used for providing mapping processing for data transmitted between a media access control (MAC) layer and the PCS. The PCS is configured to perform encoding processing or decoding processing on transmitted data in a specific encoding manner. A function of an FEC layer may be further deployed at the PCS. The FEC layer is configured to implement FEC processing. The PMD layer is configured to implement mutual conversion between a data signal at the PAM layer and a signal transmitted on a specific medium. The AUI may be configured to transmit data at different rates between the PMA layers. The MII is configured to transmit data at different rates between the RS and the PCS, and may include a plurality of types of data such as 50GMII, 100GMII, and 200G/400GMII. Sent data is output through the RS, the PCS, the PMA layer, the PMA layer, the inner FEC layer, the PMD layer, and the medium. Received data is output through the medium, the PMD layer, the inner FEC layer, the PMA layer, the PMA layer, the PCS, and the RS. A hardware structure shown in FIG. 12B includes an RS, a PCS, a PMA layer, an inner FEC layer, a PMD layer, and a medium that are sequentially arranged. An MII is disposed between the RS and the PCS. An MDI is disposed between the PMD layer and the medium. The medium may be a coaxial cable, an optical fiber, a twisted-pair cable, or the like. The data processing method in the embodiments corresponding to FIG. 2 to FIG. 11 may be implemented by the PMA layer in FIG. 12B. For functions of the RS, the PCS, the PMA layer, the inner FEC layer, the PMD layer, the medium, and the MII, refer to related content in FIG. 12A. Sent data is output through the RS, the PCS, the PMA layer, the inner FEC layer, the PMD layer, and the medium. Received data is output through the medium, the PMD layer, the inner FEC layer, the PMA layer, the PCS, and the RS. FIG. 12A or FIG. 12B may be applied to a host or chip that uses 200GBASE-R, 400GBASE-R, 800GBASE-R, or 1.6TBASE-R.

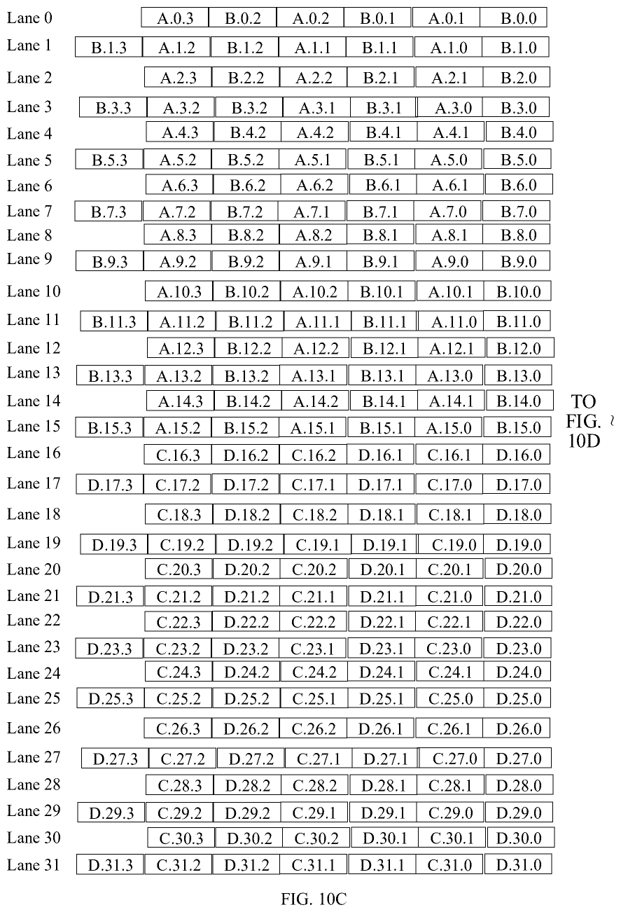

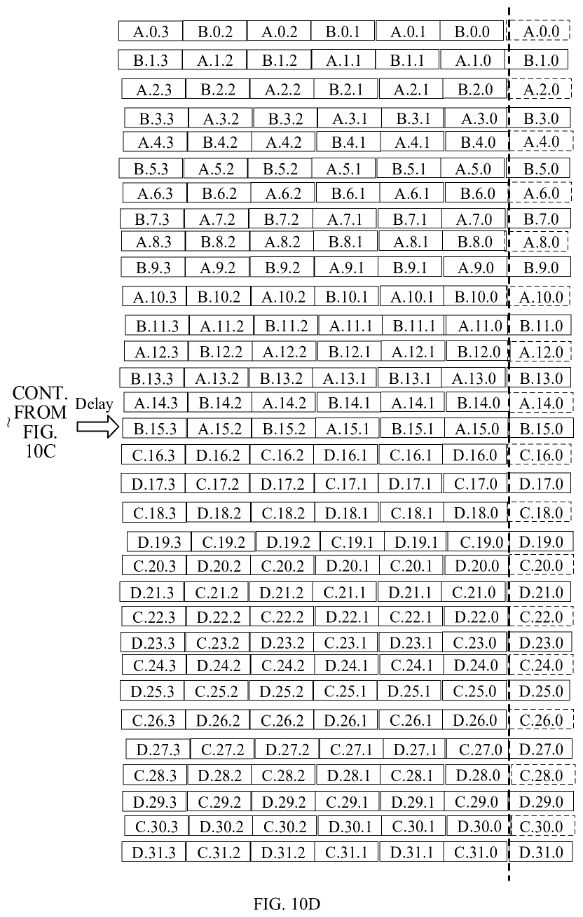

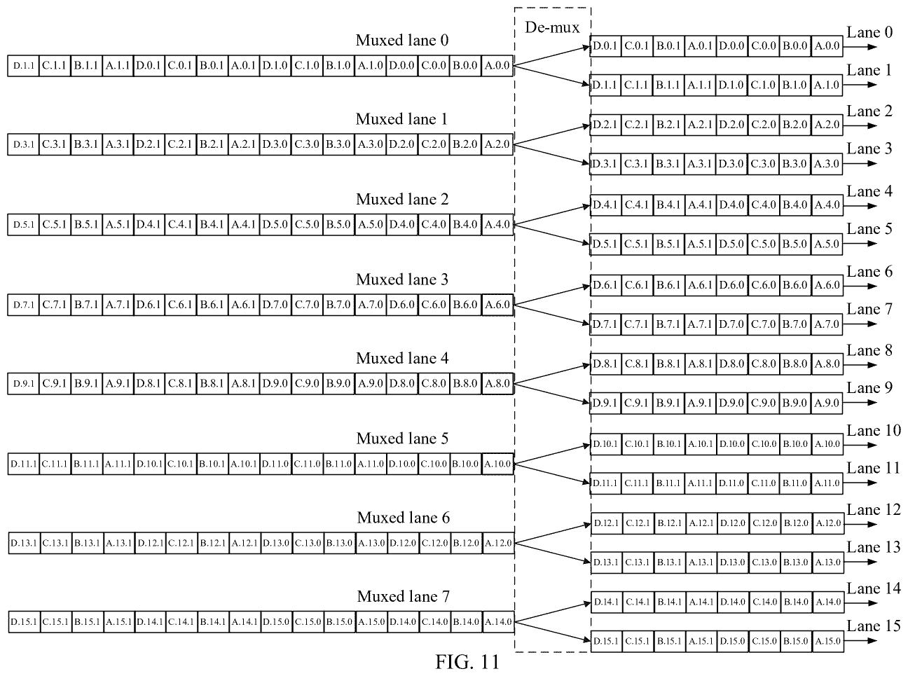

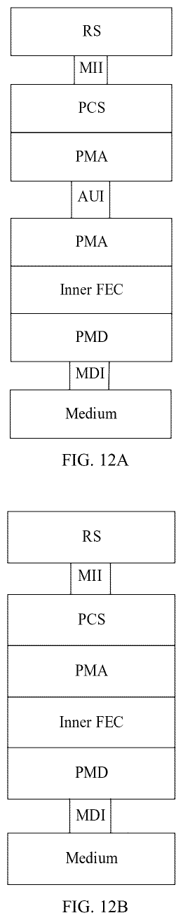

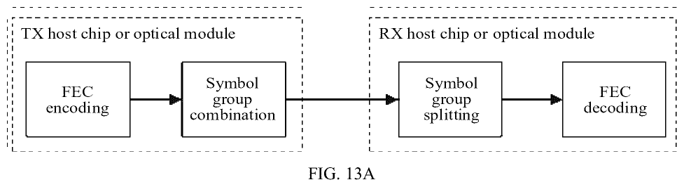

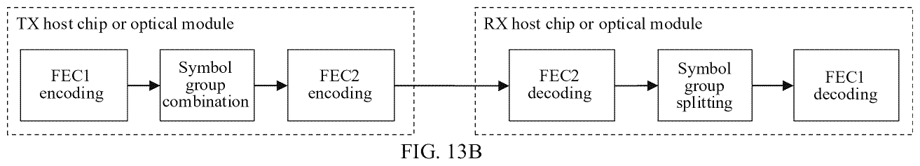

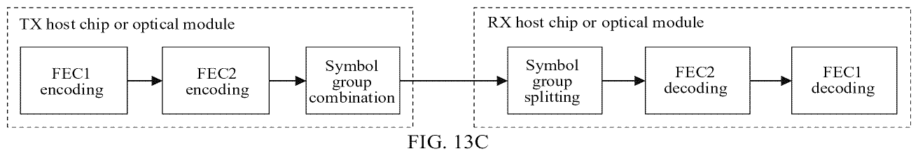

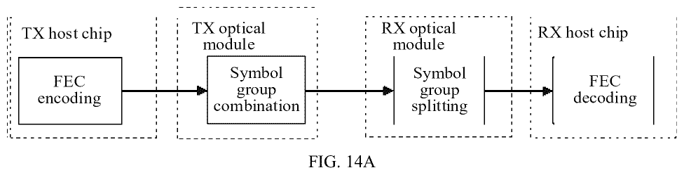

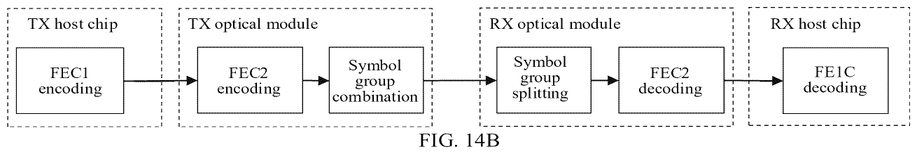

FIG. 13A to FIG. 13C are possible implementations of deploying the data processing method in the embodiments corresponding to FIG. 2 to FIG. 11 in a chip scenario. In FIG. 13A to FIG. 13C, FEC encoding or FEC1 encoding refers to first FEC encoding (for example, FEC encoding at a PCS), FEC2 encoding refers to second FEC encoding (for example, inner FEC encoding), symbol group combination refers to symbol group-based multiplexing (the data processing method in the embodiments corresponding to FIG. 2 to FIG. 6), symbol group splitting refers to symbol group-based demultiplexing (the data processing method in the embodiments corresponding to FIG. 7 to FIG. 11), FEC decoding or FEC1 decoding refers to first FEC decoding (for example, FEC decoding at the PCS), and FEC2 decoding refers to second FEC decoding (for example, inner FEC decoding). The symbol group combination may further include the shifting in the embodiments corresponding to FIG. 2 to FIG. 6. The symbol group splitting may further include the shifting in the embodiments corresponding to FIG. 7 to FIG. 11. TX indicates a transmitting side, and RX indicates a receiving side. FIG. 14A to FIG. 14F are possible implementations of deploying the data processing method in the embodiments corresponding to FIG. 2 to FIG. 11 in a scenario of a plurality of chips. In FIG. 14A to FIG. 14F, FEC encoding or FEC1 encoding refers to first FEC encoding (for example, FEC encoding at a PCS); FEC2 encoding refers to second FEC encoding (for example, inner FEC encoding); symbol group combination, symbol group combination 1, or symbol group combination 2 refers to symbol group-based multiplexing (the data processing method in the embodiments corresponding to FIG. 2 to FIG. 6); symbol group splitting, symbol group splitting 1, or symbol group splitting 2 refers to symbol group-based demultiplexing (the data processing method in the embodiments corresponding to FIG. 7 to FIG. 11); FEC decoding or FEC1 decoding refers to first FEC decoding (for example, FEC decoding at the PCS); and FEC2 decoding refers to second FEC decoding (for example, inner FEC decoding). The symbol group combination, the symbol group combination 1, or the symbol group combination 2 may further include the shifting in the embodiments corresponding to FIG. 2 to FIG. 6. The symbol group splitting, the symbol group splitting 1, or the symbol group splitting 2 may further include the shifting in the embodiments corresponding to FIG. 7 to FIG. 11. TX indicates a transmitting side, and RX indicates a receiving side. In FIG. 14A to FIG. 14F, if there is a CDR chip between a host chip and an optical module, symbol group combination, symbol group combination 1, or symbol group combination 2 at the TX side is implemented in the CDR chip, and symbol group splitting, symbol group splitting 1, or symbol group splitting 2 at the RX side is implemented in the CDR chip. Examples are not described one by one in embodiments.

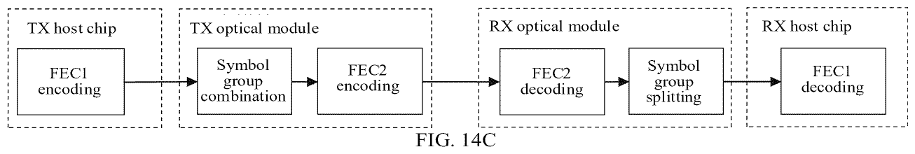

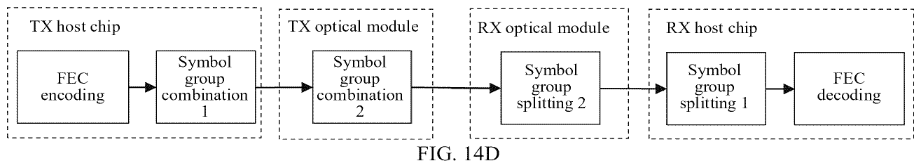

As shown in FIG. 15A, a data sending apparatus 1500 provided in an embodiment includes a processing unit 1502 and an output unit 1503. Optionally, the data sending apparatus 1500 further includes an obtaining unit 1501. The processing unit 1502 is configured to implement the method for obtaining the output data stream in 202 in the embodiment corresponding to FIG. 2. The output unit 1503 is configured to implement the output method in 202 in the embodiment corresponding to FIG. 2. The obtaining unit 1501 is configured to implement the method in 201 in the embodiment corresponding to FIG. 2. When the data sending apparatus 1500 is configured to implement the method performed by the transmitting end in FIG. 3 to FIG. 6, the processing unit 1502 is configured to implement the multiplexing method in the embodiments corresponding to FIG. 3 to FIG. 6, the output unit 1503 is configured to implement the method for outputting the data stream through the muxed lane in the embodiments corresponding to FIG. 3 to FIG. 6, and the obtaining unit 1501 is configured to implement one or more methods of the shifting and the interleaving in the embodiments corresponding to FIG. 3 to FIG. 6.

For example, the processing unit 1502 is configured to multiplex a data streams based on a symbol group to obtain b data streams, where a is an integer greater than or equal to 2, b is an integer greater than or equal to 1 and b<a, any one of the b data streams includes a plurality of symbol groups, any symbol group includes a plurality of symbols from different codewords, and any symbol includes a plurality of bits. The output unit 1503 is configured to transmit the b data streams.

The a data streams include a first data stream and a second data stream, the b data streams include a third data stream, the plurality of symbol groups include a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

For example, the a data streams are based on encoding, and the symbol is an RS symbol. A length of the RS symbol is 10 bits.

In an implementation of 200GBASE-R, a is equal to 8, b is equal to 1, a quantity of symbols included in the symbol group is 2, and any eight consecutive symbol groups included in the b data streams respectively come from the eight data streams. The processing unit 1502 is further configured to delay, by 136*N+1 symbols, sending of a data stream output through each lane with an odd sequence number in the a data streams, where N is an integer greater than or equal to 1.

In an implementation of 400GBASE-R, a is equal to 16, b is equal to 2, a quantity of symbols included in the symbol group is 2, and any eight consecutive symbol groups included in any one of the b data streams respectively come from eight data streams in the a data streams. The processing unit 1502 is further configured to delay, by 68*N+1 symbols, sending of a data stream output through each lane with an odd sequence number in the a data streams, where N is an integer greater than or equal to 1.

In an implementation of 1.6TBASE-R, a is equal to 16, b is equal to 8, a quantity of symbols included in the symbol group is 4, and any two consecutive symbol groups included in any one of the b data streams respectively come from two data streams in the a data streams.

Based on any one of the foregoing implementations, an order of codewords to which consecutive symbols output through any lane with an even sequence number in the a data streams belong is the same as an order of codewords to which consecutive symbols output through any lane with an odd sequence number in the a data streams belong.

In a possible implementation of 800GBASE-R, a is equal to 32, b is equal to 4, a quantity of symbols included in the symbol group is 2, and any eight consecutive symbol groups included in any one of the b data streams respectively come from eight data streams in the a data streams, where the eight data streams in the a data streams include four data streams from a first codeword group and four data streams from a second codeword group, the first codeword group includes two codewords, the second codeword group includes two codewords, and the two codewords included in the first codeword group are different from the two codewords included in the second codeword group. The processing unit 1502 is further configured to delay, by 2*N+1 symbols, sending of a data stream output through each lane with an odd sequence number in the a data streams, where N is an integer greater than or equal to 0.

In an implementation, the obtaining unit 1501 is further configured to: encode received data to obtain K codeword groups, where K is an integer greater than or equal to 1, and a quantity of symbols included in any codeword in the K codeword groups is a positive integer multiple of 544; and interleave, based on the symbol, codewords included in the K codeword groups, to obtain the a data streams. The encoding includes forward error correction FEC encoding.

In an implementation, a sum of rates of the a data streams is the same as a sum of rates of the b data streams. A rate of any one of the b data streams is 200 Gbps.

As shown in FIG. 15B, a data receiving apparatus 1510 provided in an embodiment includes an obtaining unit 1511 and a processing unit 1512. The obtaining unit 1511 is configured to implement the method in 701 in the embodiment corresponding to FIG. 7. The processing unit 1512 is configured to implement the method in 702 in the embodiment corresponding to FIG. 7. When the data receiving apparatus 1510 is configured to implement the method performed by the receiving end in FIG. 8 to FIG. 11, the obtaining unit 1511 is configured to obtain the input data stream through the muxed lane in the embodiments corresponding to FIG. 8 to FIG. 11, and the processing unit 1513 is configured to implement the demultiplexing method in the embodiments corresponding to FIG. 8 to FIG. 11. Further, the processing unit 1513 is configured to implement the shifting method in the embodiments corresponding to FIG. 8 to FIG. 11. A function performed by the unit included in the receiving apparatus is a reverse process of the method performed by the unit included in the sending apparatus. Details are not described herein again.

For example, the obtaining unit 1511 is configured to receive b data streams, where b is an integer greater than or equal to 1, any one of the b data streams includes a plurality of symbol groups, any symbol group includes a plurality of symbols from different codewords, and any symbol includes a plurality of bits; and the processing unit 1512 is configured to demultiplex the b data streams based on the symbol group to obtain a data streams, where a is an integer greater than or equal to 2, and a>b.

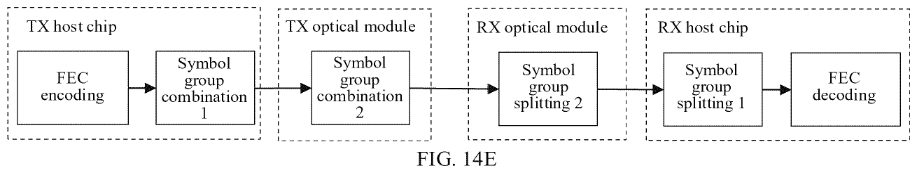

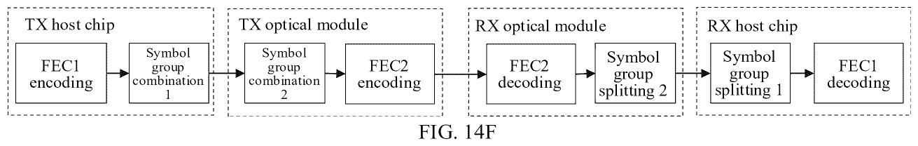

As shown in FIG. 16A, another data sending apparatus 1600 provided in an embodiment includes a processor 1601 and a transmitter 1602 coupled to the processor 1601. The processor 1601 is configured to implement the method for obtaining the output data stream in 201 and 202 in the embodiment corresponding to FIG. 2. The transmitter 1602 is configured to implement the output method in 202 in the embodiment corresponding to FIG. 2. When the data sending apparatus 1600 is configured to implement the method performed by the transmitting end in FIG. 3 to FIG. 6, the processor 1601 is configured to implement the multiplexing method in the embodiments corresponding to FIG. 3 to FIG. 6, and the transmitter 1602 is configured to implement the method for outputting the data stream through the muxed lane in the embodiments corresponding to FIG. 3 to FIG. 6. Optionally, the processor 1601 is further configured to implement one or more methods of the shifting and the interleaving in the embodiments corresponding to FIG. 3 to FIG. 6. The processor 1601 may use the structure in FIG. 12A or FIG. 12B. The transmitter 1602 may be specifically a sending circuit or a sending interface. The data sending apparatus 1600 may be a router, a switch, or an optical module. When the data sending apparatus 1600 is a router or a switch, the processor 1601 may be a physical layer (PHY) chip, for example, the TX host chip in FIG. 13 and FIG. 14, and the transmitter 1602 may be an optical module, for example, the TX optical module in FIG. 13 and FIG. 14. When the data sending apparatus 1600 is an optical module, for example, the TX optical module in FIG. 13 to FIG. 14, the processor 1601 may be a processing circuit, and the transmitter 1602 may be a sending circuit.

For example, the processor 1601 is configured to multiplex a data streams based on a symbol group to obtain b data streams, where a is an integer greater than or equal to 2, b is an integer greater than or equal to 1 and b<a, any one of the b data streams includes a plurality of symbol groups, any symbol group includes a plurality of symbols from different codewords, and any symbol includes a plurality of bits. The transmitter 1602 is configured to transmit the b data streams.

In a possible implementation, the a data streams include a first data stream and a second data stream, the b data streams include a third data stream, the plurality of symbol groups include a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

In a possible implementation, the a data streams are based on RS encoding, and the symbol is an RS symbol.

In a possible implementation, a length of the RS symbol is 10 bits.

In a possible implementation, a is equal to 8, b is equal to 1, a quantity of symbols included in the symbol group is 2, and any eight consecutive symbol groups included in the b data streams respectively come from the eight data streams.

In a possible implementation, the processor is further configured to delay, by L symbols, sending of a data stream output through each lane with an odd sequence number in the a data streams, where L is equal to 136*N+1, and N is an integer greater than or equal to 1.

In a possible implementation, a is equal to 16, b is equal to 2, a quantity of symbols included in the symbol group is 2, and any eight consecutive symbol groups included in any one of the b data streams respectively come from eight data streams in the a data streams.

In a possible implementation, the processor is further configured to delay, by L symbols, sending of a data stream output through each lane with an odd sequence number in the a data streams, where L is equal to 68*N+1, and N is an integer greater than or equal to 1.

In a possible implementation, a is equal to 16, b is equal to 8, a quantity of symbols included in the symbol group is 4, and any two consecutive symbol groups included in any one of the b data streams respectively come from two data streams in the a data streams.

In a possible implementation, an order of codewords to which consecutive symbols output through any lane with an even sequence number in the a data streams belong is the same as an order of codewords to which consecutive symbols output through any lane with an odd sequence number in the a data streams belong.

In a possible implementation, a is equal to 32, b is equal to 4, a quantity of symbols included in the symbol group is 2, and any eight consecutive symbol groups included in any one of the b data streams respectively come from eight data streams in the a data streams, where the eight data streams in the a data streams include four data streams from a first codeword group and four data streams from a second codeword group, the first codeword group includes two codewords, the second codeword group includes two codewords, and the two codewords included in the first codeword group are different from the two codewords included in the second codeword group.

In a possible implementation, the processor is further configured to delay, by L symbols, sending of a data stream output through each lane with an odd sequence number in the a data streams, where L is equal to 2*N+1, and N is an integer greater than or equal to 0.

In a possible implementation, the processor is further configured to: encode received data to obtain K codeword groups, where K is an integer greater than or equal to 1, and a quantity of symbols included in any codeword in the K codeword groups is a positive integer multiple of 544; and interleave, based on the symbol, codewords included in the K codeword groups, to obtain the a data streams.

In a possible implementation, the encoding includes forward error correction FEC encoding.

In a possible implementation, a sum of rates of the a data streams is the same as a sum of rates of the b data streams.

In a possible implementation, a rate of any one of the b data streams is 200 Gbps.

As shown in FIG. 16B, another data receiving apparatus 1610 provided in an embodiment includes a receiver 1611 and a processor 1612 coupled to the receiver 1611. The receiver 1611 is configured to implement the method in 701 in the embodiment corresponding to FIG. 7. The processor 1612 is configured to implement the method in 702 in the embodiment corresponding to FIG. 7. When the data receiving apparatus 1610 is configured to implement the method performed by the receiving end in FIG. 8 to FIG. 11, the receiver 1611 is configured to obtain the input data stream through the muxed lane in the embodiments corresponding to FIG. 8 to FIG. 11, and the processor 1612 is configured to implement the demultiplexing method in the embodiments corresponding to FIG. 8 to FIG. 11. Further, the processor 1612 is configured to implement the shifting method in the embodiments corresponding to FIG. 8 to FIG. 11. The processor 1612 may use the structure in FIG. 12A or FIG. 12B. The receiver 1611 may be specifically a receiving circuit or a receiving interface. The data receiving apparatus 1610 may be a router, a switch, or an optical module. When the data receiving apparatus 1610 is a router or a switch, the processor 1612 may be a PHY chip, for example, the RX host chip in FIG. 13 and FIG. 14, and the receiver 1612 may be an optical module, for example, the RX optical module in FIG. 13 and FIG. 14. When the data receiving apparatus 1610 is an optical module, for example, the RX optical module in FIG. 13 and FIG. 14, the processor 1612 may be a processing circuit, and the receiver 1611 may be a receiving circuit.

For example, the receiver 1611 is configured to receive b data streams, where b is an integer greater than or equal to 1, any one of the b data streams includes a plurality of symbol groups, any symbol group includes a plurality of symbols from different codewords, and any symbol includes a plurality of bits; and the processor 1612 is configured to demultiplex the b data streams based on the symbol group to obtain a data streams, where a is an integer greater than or equal to 2, and a>b. The a data streams include a first data stream and a second data stream, the b data streams include a third data stream, the plurality of symbol groups include a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

In a possible implementation, the a data streams are based on RS encoding, and the symbol is an RS symbol. A length of the RS symbol is 10 bits.

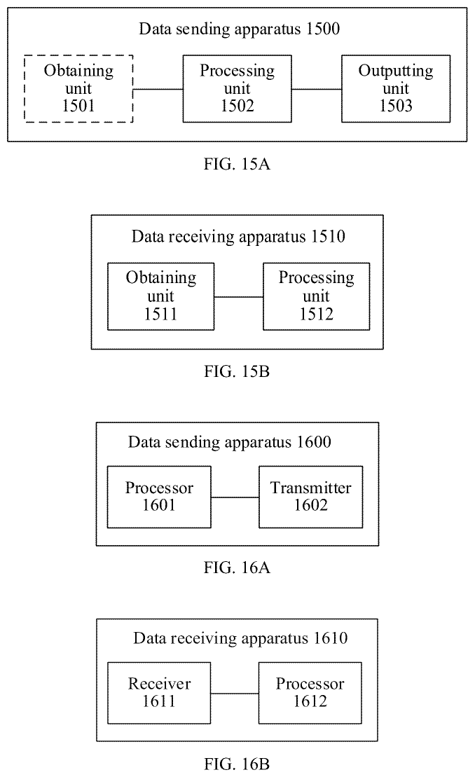

FIG. 17 is a diagram of a structure of a data processing apparatus according to an embodiment. The apparatus is an apparatus in which the transmitting end provided in embodiments is located, or is an apparatus in which the receiving end provided in embodiments is located. The apparatus includes a processor 1701, a memory 1702, a network interface 1703, and a bus 1704. The memory 1702 stores a computer program 1705, and the computer program 1705 is used to implement various functions. The processor 1701 is configured to execute the computer program 1705 to implement the data processing method provided in any one of the foregoing method embodiments. For example, the processor 1701 may be configured to execute the computer program 1705 to implement a function of each unit or structure shown in FIG. 15 or FIG. 16. The processor 1701 may be a central processing unit (CPU), or the processor 1701 may be another general-purpose processor, a digital signal processor (DSP), an ASIC, a field-programmable gate array (FPGA), a graphics processing unit (GPU) or another programmable logic device, a discrete gate or transistor logic device, a discrete hardware component, or the like. The general-purpose processor may be a microprocessor or any other processor. The memory 1702 may be a volatile memory or a non-volatile memory, or may include both a volatile memory and a non-volatile memory. The non-volatile memory may be a read-only memory (ROM), a programmable ROM (PROM), an erasable PROM (EPROM), an electrically erasable PROM (EEPROM), or a flash memory. The volatile memory may be a random-access memory (RAM) that is used as an external cache. Through example but not limitative description, many forms of RAMs are available, for example, a static RAM (SRAM), a dynamic RAM (DRAM), a synchronous DRAM (SDRAM), a double data rate (DDR) SDRAM, an enhanced SDRAM (ESDRAM), a synchronous-link DRAM (SLDRAM), and a direct Rambus (DR) RAM. There may be a plurality of network interfaces 1703, and the network interface 1703 is configured to implement a communication connection (which may be wired or wireless) to another device. The another device may be an optical module, a host, a router, a switch, or the like.

An embodiment further provides a computer-readable storage medium. The computer-readable storage medium stores instructions. When the instructions are run on a processor, the processor is enabled to perform the steps performed by the transmitting end or the receiving end in the foregoing method embodiments.

An embodiment further provides a computer program product including instructions. When the instructions are run on a processor, the processor is enabled to perform the steps performed by the transmitting end or the receiving end in the foregoing method embodiments.

An embodiment further provides a system, including a transmitting end and a receiving end. The transmitting end may be the data sending apparatus shown in FIG. 15A or FIG. 16A, or the transmitting end is configured to perform the method used by the transmitting end in the embodiments corresponding to FIG. 2 to FIG. 6. The receiving end may be the data receiving apparatus shown in FIG. 15B or FIG. 16B, or the receiving end is configured to perform the method used by the receiving end in the embodiments corresponding to FIG. 7 to FIG. 11.

In embodiments, the terms “first”, “second”, and “third” are merely used for description, and shall not be understood as an indication or implication of relative importance. In embodiments, the term “at least one” indicates one or more, and “a plurality of” indicates two or more. The term “and/or” in embodiments describes only an association relationship for describing associated objects and represents that three relationships may exist. For example, A and/or B may represent the following three cases: Only A exists, both A and B exist, and only B exists. In addition, the character “/” in this specification usually indicates an “or” relationship between the associated objects.

The foregoing descriptions are merely optional implementations, but the protection scope is not limited thereto. Any equivalent modification or replacement readily figured out by a person skilled in the art within the technical scope disclosed shall fall within the protection scope of this disclosure. Therefore, the protection scope shall be subject to the protection scope of the claims.

1. A data transmission method, wherein the method comprises:
multiplexing a data streams based on a symbol group to obtain b data streams, wherein a is an integer greater than or equal to 2, b is an integer greater than or equal to 1 and b<a, any one of the b data streams comprises a plurality of symbol groups, any symbol group comprises a plurality of symbols from different codewords, and any symbol comprises a plurality of bits; and
transmitting the b data streams.

2. The method according to claim 1, wherein the a data streams comprise a first data stream and a second data stream, the b data streams comprise a third data stream, the plurality of symbol groups comprise a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

3. The method according to claim 1, wherein the a data streams are based on Reed-Solomon (RS) encoding, and the symbol is an RS symbol.

4. The method according to claim 3, wherein a length of the RS symbol is 10 bits.

5. The method according to claim 1, wherein a is equal to 8, b is equal to 1, a quantity of symbols comprised in the symbol group is 2, and any eight consecutive symbol groups comprised in the b data streams respectively come from the eight data streams.

6. The method according to claim 5, wherein before the multiplexing a data streams based on a symbol group to obtain b data streams, the method further comprises: delaying, by L symbols, sending of a data stream output through each lane with an odd sequence number in the a data streams, wherein L is equal to 136*N+1, and N is an integer greater than or equal to 1.

7. The method according to claim 1, wherein a is equal to 16, b is equal to 2, a quantity of symbols comprised in the symbol group is 2, and any eight consecutive symbol groups comprised in any one of the b data streams respectively come from eight data streams in the a data streams.

8. The method according to claim 7, wherein before the multiplexing a data streams based on a symbol group to obtain b data streams, the method further comprises: delaying, by L symbols, sending of a data stream output through each lane with an odd sequence number in the a data streams, wherein L is equal to 68*N+1, and N is an integer greater than or equal to 1.

9. The method according to claim 1, wherein a is equal to 16, b is equal to 8, a quantity of symbols comprised in the symbol group is 4, and any two consecutive symbol groups comprised in any one of the b data streams respectively come from two data streams in the a data streams.

10. The method according to claim 1, wherein an order of codewords to which consecutive symbols output through any lane with an even sequence number in the a data streams belong is the same as an order of codewords to which consecutive symbols output through any lane with an odd sequence number in the a data streams belong.

11. The method according to claim 1, wherein a is equal to 32, b is equal to 4, a quantity of symbols comprised in the symbol group is 2, and any eight consecutive symbol groups comprised in any one of the b data streams respectively come from eight data streams in the a data streams, wherein the eight data streams in the a data streams comprise four data streams from a first codeword group and four data streams from a second codeword group, the first codeword group comprises two codewords, the second codeword group comprises two codewords, and the two codewords comprised in the first codeword group are different from the two codewords comprised in the second codeword group.

12. The method according to claim 11, wherein before the multiplexing a data streams based on a symbol group to obtain b data streams, the method further comprises: delaying, by L symbols, sending of a data stream output through each lane with an odd sequence number in the a data streams, wherein L is equal to 2*N+1, and N is an integer greater than or equal to 0.

13. The method according to claim 1, wherein the method further comprises:
encoding received data to obtain K codeword groups, wherein K is an integer greater than or equal to 1, and a quantity of symbols comprised in any codeword in the K codeword groups is a positive integer multiple of 544; and
interleaving, based on the symbol, codewords comprised in the K codeword groups, to obtain the a data streams.

14. The method according to claim 13, wherein the encoding comprises forward error correction (FEC) encoding.

15. The method according to claim 1, wherein a sum of rates of the a data streams is the same as a sum of rates of the b data streams.

16. The method according to claim 1, wherein a rate of any one of the b data streams is 200 Gbps.

17. A data transmission method, wherein the method comprises:
receiving b data streams, wherein b is an integer greater than or equal to 1, any one of the b data streams comprises a plurality of symbol groups, any symbol group comprises a plurality of symbols from different codewords, and any symbol comprises a plurality of bits; and
demultiplexing the b data streams based on the symbol group to obtain a data streams,
wherein a is an integer greater than or equal to 2, and
$$a > b .$$

18. The method according to claim 17, wherein the a data streams comprise a first data stream and a second data stream, the b data streams comprise a third data stream, the plurality of symbol groups comprise a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

19. The method according to claim 17, wherein the a data streams are based on Reed-Solomon (RS) encoding, and the symbol is an RS symbol.

20. The method according to claim 19, wherein a length of the RS symbol is 10 bits.

21. A data processing apparatus, wherein the apparatus comprises:
a multiplexer, configured to multiplex a data streams based on a symbol group to obtain b data streams, wherein a is an integer greater than or equal to 2, b is an integer greater than or equal to 1 and b<a, any one of the b data streams comprises a plurality of symbol groups, any symbol group comprises a plurality of symbols from different codewords, and any symbol comprises a plurality of bits; and
a transmitter, configured to transmit the b data streams.

22. The apparatus according to claim 21, wherein the a data streams comprise a first data stream and a second data stream, the b data streams comprise a third data stream, the plurality of symbol groups comprise a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

23. The apparatus according to claim 21, wherein the a data streams are based on Reed-Solomon (RS) encoding, and the symbol is an RS symbol.

24. The apparatus according to claim 23, wherein a length of the RS symbol is 10 bits.

25. The apparatus according to claim 21, wherein a is equal to 8, b is equal to 1, a quantity of symbols comprised in the symbol group is 2, and any eight consecutive symbol groups comprised in the b data streams respectively come from the eight data streams.

26. The apparatus according to claim 25, wherein the multiplexer is further configured to: delay, by L symbols, sending of a data stream output through each lane with an odd sequence number in the a data streams, wherein L is equal to 136*N+1, and N is an integer greater than or equal to 1.

27. The apparatus according to claim 21, wherein a is equal to 16, b is equal to 2, a quantity of symbols comprised in the symbol group is 2, and any eight consecutive symbol groups comprised in any one of the b data streams respectively come from eight data streams in the a data streams.

28. The apparatus according to claim 27, wherein the multiplexer is further configured to: delay, by L symbols, sending of a data stream output through each lane with an odd sequence number in the a data streams, wherein L is equal to 68*N+1, and N is an integer greater than or equal to 1.

29. The apparatus according to claim 21, wherein a is equal to 16, b is equal to 8, a quantity of symbols comprised in the symbol group is 4, and any two consecutive symbol groups comprised in any one of the b data streams respectively come from two data streams in the a data streams.

30. The apparatus according to claim 21, wherein an order of codewords to which consecutive symbols output through any lane with an even sequence number in the a data streams belong is the same as an order of codewords to which consecutive symbols output through any lane with an odd sequence number in the a data streams belong.

31. The apparatus according to claim 21, wherein a is equal to 32, b is equal to 4, a quantity of symbols comprised in the symbol group is 2, and any eight consecutive symbol groups comprised in any one of the b data streams respectively come from eight data streams in the a data streams, wherein the eight data streams in the a data streams comprise four data streams from a first codeword group and four data streams from a second codeword group, the first codeword group comprises two codewords, the second codeword group comprises two codewords, and the two codewords comprised in the first codeword group are different from the two codewords comprised in the second codeword group.

32. The apparartus according to claim 31, wherein the multiplexer is further configured to: delaying, by L symbols, sending of a data stream output through each lane with an odd sequence number in the a data streams, wherein L is equal to 2*N+1, and N is an integer greater than or equal to 0.

33. The apparatus according to claim 31, wherein the apparatus further comprises:
an encoder, configured to encode received data to obtain K codeword groups, wherein K is an integer greater than or equal to 1, and a quantity of symbols comprised in any codeword in the K codeword groups is a positive integer multiple of 544; and
an interleaver, configured to interleave, based on the symbol, codewords comprised in the K codeword groups, to obtain the a data streams.

34. The apparatus according to claim 33, wherein the encoder is configured to perform forward error correction (FEC) encoding on the received data to obtain K codeword groups.

35. The apparutus according to claim 31, wherein a sum of rates of the a data streams is the same as a sum of rates of the b data streams.

36. The apparatus according to claim 31, wherein a rate of any one of the b data streams is 200 Gbps.

37. A data transmission apparatus, wherein the apparatus comprises:
a receiver, configured to receive b data streams, wherein b is an integer greater than or equal to 1, any one of the b data streams comprises a plurality of symbol groups, any symbol group comprises a plurality of symbols from different codewords, and any symbol comprises a plurality of bits; and
a demultiplexer, configured to demultiplex the b data streams based on the symbol group to obtain a data streams,
wherein a is an integer greater than or equal to 2, and
a>b.

38. The apparatus according to claim 37, wherein the a data streams comprise a first data stream and a second data stream, the b data streams comprise a third data stream, the plurality of symbol groups comprise a first symbol group and a second symbol group, the first symbol group and the second symbol group are consecutive in the third data stream, all symbols in the first symbol group come from the first data stream and are consecutive in the first data stream, and all symbols in the second symbol group come from the second data stream and are consecutive in the second data stream.

39. The apparatus according to claim 37, wherein the a data streams are based on Reed-Solomon (RS) encoding, and the symbol is an RS symbol.

40. The apparauts according to claim 39, wherein a length of the RS symbol is 10 bits.
